(19) United States
(12) Patent Application Publication
(10) Pub. No.: US 2025/0362333 A1
(43) Pub. Date: Nov. 27, 2025

(54) ELECTROSTATIC FIELD STRENGTH MEASURING APPARATUS, DETECTING APPARATUS, METHOD OF MEASURING ELECTROSTATIC FIELD STRENGTH OF TARGET OBJECT

(71) Applicant: Taiwan Semiconductor Manufacturing Company, Ltd., Hsinchu (TW)

(72) Inventors: Ming Da Yang, Taichung City (TW); Chun-Hsuan Lin, Hsinchu County (TW); Yi-Chen Li, Taichung City (TW)

(73) Assignee: Taiwan Semiconductor Manufacturing Company, Ltd., Hsinchu (TW)

(21) Appl. No.: 19/294,343

(22) Filed: Aug. 8, 2025

Related U.S. Application Data
(63) Continuation of application No. 18/480,482, filed on Oct. 3, 2023.

(51) Int. Cl. G01R 29/12

(52) U.S. Cl. CPC G01R 29/12

(57) ABSTRACT

An electrostatic field strength measuring apparatus includes an electrostatic field detection device and a processor. The electrostatic field detection device includes a ring-shaped light source configured to emit a light signal to a target object, and a reflection detector disposed within and surrounded by the ring-shaped light source and configured to receive a reflection signal, of the light signal, reflected by a surface of the target object and generate an electrical signal based upon the reflection signal. The processor is configured to determine, based upon the electrical signal, measures of electrostatic field strength at the surface of the target object.

### CROSS-REFERENCE TO RELATED APPLICATION

This is a continuation application of patent application Ser. No. 18/480,482, filed on Oct. 3, 2023. The entirety of each of the above-mentioned patent applications is hereby incorporated by reference herein and made a part of this specification.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more components are used in semiconductor fabrication to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of an apparatus, in accordance with some embodiments.

FIG. 2 illustrates a perspective view of an apparatus, in accordance with some embodiments.

FIG. 3 illustrates a schematic view of an apparatus, in accordance with some embodiments.

FIG. 4 illustrates a partial enlarged view of an apparatus, in accordance with some embodiments.

FIG. 5 illustrates a partial enlarged view of an apparatus, in accordance with some embodiments.

FIG. 6 illustrates a perspective view of a target object, in accordance with some embodiments.

FIG. 7 illustrates a visual image of a target object generated using an image sensor of an apparatus, in accordance with some embodiments.

FIG. 8 illustrates a representation of a plurality of pixel colors determined based upon a plurality of measures of electrostatic field strength, in accordance with some embodiments.

FIG. 9 illustrates an electrostatic field strength map generated by an apparatus, in accordance with some embodiments.

FIG. 10 illustrates a perspective view of an apparatus and a target object, in accordance with some embodiments.

FIG. 11 illustrates a perspective view of an apparatus and a target object, in accordance with some embodiments.

FIG. 12 illustrates a perspective view of an apparatus and a target object, in accordance with some embodiments.

FIG. 13 illustrates an electrostatic field strength map generated by an apparatus, in accordance with some embodiments.

FIG. 14 illustrates a schematic view of a system, in accordance with some embodiments.

FIG. 15 illustrates an electrostatic information display system displaying electrostatic event information, in accordance with some embodiments.

FIG. 16 is a flow diagram illustrating a method, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments, a detecting apparatus has a ring light source and a reflection detector. The ring light source is in a ring shape for surrounding the reflection detector, and configured to emit a light signal to a target object. The reflection detector is configured to receive a reflection signal including light, of the light signal, reflected by a surface of the target object. The light of the light signal being reflected by the surface generates one or more additional harmonics in the reflection signal, such as due, at least in part, by second harmonic generation that occurs when the light signal is reflected by the surface. Accordingly, the reflection signal includes first harmonic light having an original wavelength of the light signal generated by the ring light source and second harmonic light having a wavelength that is about half of the original wavelength. An intensity of the second harmonic light within the reflection signal is reflective of an electrostatic field strength at the surface of the target object. In some embodiments, an increase in the intensity of the second harmonic light is reflective of a higher value of the electrostatic field strength at the surface.

In some embodiments, the ring light source includes a plurality of first photodiodes a plurality of second photodiodes. The first photodiodes are configured to emit a first light signal with a first wavelength to the target object, and the second photodiodes are configured to emit a second light signal with a second wavelength to the target object. The second wavelength is different from the first wavelength. Accordingly, the reflection detector is configured to receive a first reflection signal reflected by the surface of the target object, and a second reflection signal reflected by the surface of the target object, so as to obtain electrostatic field strengths for two different materials on the surface of the target object.

In some embodiments, the reflection detector includes an optical filter that that filters the reflection signal to provide filtered light, including the second harmonic light, to a light sensor. In some embodiments, the optical filter filters the reflection signal by blocking light, of the reflection signal, other than the second harmonic light. The light sensor generates an electrical signal based upon the filtered light. The electrical signal is indicative of an intensity of the filtered light. In some embodiments, the intensity of the filtered light is about equal to the intensity of the second harmonic light in the reflection signal, such as due, at least in part, to the light other than the second harmonic light being filtered out of the filtered light by the optical filter. The processor determines, based upon the electrical signal, measures of electrostatic field strength at the surface. In some embodiments, an electrostatic field strength map is generated based upon the measures of electrostatic field strength.

In some embodiments, the processor is configured to detect an electrostatic event at the target object, e.g., a semiconductor fabrication component, using at least one of the electrostatic field strength map or the measures of electrostatic field strength. In some embodiments, the electrostatic event corresponds to at least one of an accumulation of electrostatic charge, an electrostatic field hotspot, or a potential electrostatic discharge (ESD) event at the semiconductor fabrication component.

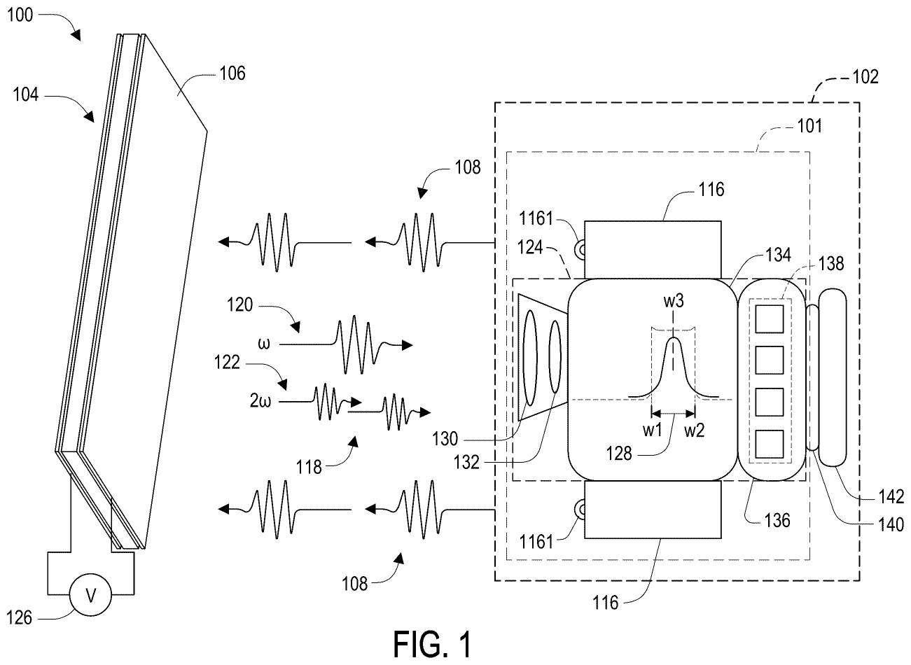

FIG. 1 illustrates a schematic view of an apparatus, in accordance with some embodiments. In some embodiments, the apparatus 102 is configured to determine measures a characteristic of a target object 104. For example, in the present embodiment, the apparatus 102 is an electrostatic field strength measuring apparatus configured to determine measures of electrostatic field strength at a surface 106 of the target object 104. In some embodiments, the target object 104 includes a semiconductor fabrication component, such as at least one of (i) physical vapor deposition (PVD) equipment, such as plasma enhanced PVD equipment, (ii) chemical vapor deposition (CVD) equipment, (iii) plating equipment, (iv) etching equipment, such as at least one of plasma etching equipment, wet etching equipment or dry etching equipment, (v) lithography equipment, (vi) chemical mechanical planarization (CMP) equipment, (vii) semiconductor wafer storage equipment, such as a front opening unified pod (FOUP), (viii) a component that utilizes plasma, (ix) a tube, such as at least one of a pipe, an insulated tube, or other type of tube that is configured to conduct fluid including at least one of liquid or gas, (x) a manifold, (xi) fluid storage equipment configured to store fluid including at least one of liquid or gas, (xii) a processing chamber, (xiii) a pump, (xiv) a robotic arm, (xv) one or more stocker tools, (xvi) one or more management tools, (xvii) one or more handling tools, (xviii) inspection equipment, (xix) an automated material handling system, (xx) an automated transport system, (xxi) a lorry tank, (xxii) a mask, (xxiii) a mask box, or (xxiv) other equipment. In some embodiments, a measure of electrostatic field strength determined by the apparatus 102 corresponds to at least one of a measure of electrostatic charge accumulation, a voltage level 126, an electrostatic field strength amplitude, or other measure. In other embodiments, the apparatus 102 may also be used to determine measures of other characteristic such as a dimension of the surface 106 of the target object 104, or a distance from the reflection detector 124 to the surface 106 of the target object 104. The disclosure does not limit the application of the apparatus 102.

In some embodiments, the apparatus 102 includes a ring light source 116 configured to emit a light signal 108 to the target object 104. In some embodiments, the ring light source 116 includes a plurality of photodiodes 1161, such as injection light diodes, a laser diodes, light-emitting diodes, or other light generating devices, etc. In one embodiment, the ring light source 116 is a laser source in a ring shape, and configured to emit a laser signal 108 to the target object 104. The laser signal 108 includes at least one of a series of laser pulses, or a continuous laser. However, the disclosure is not limited thereto. In some embodiments, the ring light source 116 performs laser scanning cycles in which the ring light source 116 uses the light signal 108 to scan across the target object 104 in at least one of a horizontal direction or a vertical direction. In some embodiments, in a scanning cycle performed using the ring light source 116, the light signal 108 impinges upon a plurality of points across the surface 106 of the target object 104. A time duration of a scanning cycle performed by the ring light source 116 is between about 1 micro-second to about 1 second. Other values of the time duration are within the scope of the present disclosure.

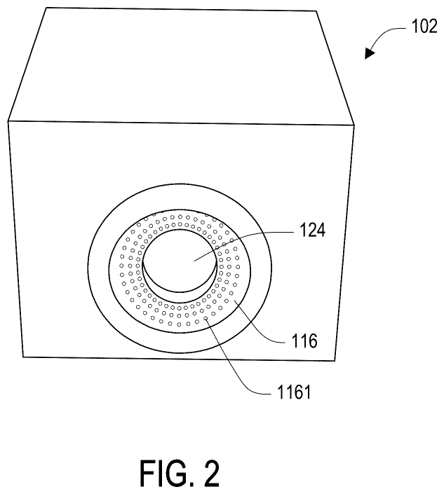

FIG. 2 illustrates a perspective view of an apparatus, in accordance with some embodiments. Referring to FIG. 1 and FIG. 2, in some embodiments, the ring light source 116 is in a ring shape and configured to surround the reflection detector 124 therein. In detail, the ring light source 116 includes a plurality of photodiodes 1161 distributed evenly over the ring light source 116 such that the reflection detector 124 is surrounded by the photodiodes 1161. In one embodiment, the photodiodes 1161 may be laser diodes, or the like. Accordingly, the light signal 108 emitted by the photodiodes 1161 can impinge upon the surface 106 of the target object 104 more evenly and a reflection signal reflected by the surface 106 of the target object 104 can be received by the reflection detector 124 more evenly.

In some embodiments, the apparatus 102 includes a reflection detector 124 disposed within and surrounded by the ring light source 116, and the reflection detector 124 is configured to receive a reflection signal 118 including light, of the light signal 108, reflected by the surface 106 of the target object 104. In one embodiment, the reflection signal 118 includes first harmonic light 120 “ω” and second harmonic light 122 “2ω”. The second harmonic light 122 is generated via second-harmonic generation (also called frequency doubling) that occurs when the light of the light signal 108 is reflected by the surface 106 of the target object 104. As a result of the second-harmonic generation, two photons of the light of the light signal 108 are combined to generate a new photon in the reflection signal 118 with about twice the energy of the two photons, about twice the frequency of the two photons, and about half the wavelength of the two photons. Thus, a reflected wavelength of the second harmonic light 122 in the reflection signal 118 is about half of the (initial) wavelength of the first harmonic light 120 in the reflection signal 118.

In some embodiments, the reflection detector 124 may further includes at least one light sensor 136, an optical filter 134, or one or more lenses. The one or more lenses are configured to conduct the reflection signal 118 to the optical filter 134. In some embodiments, the one or more lenses includes at least one of a focus lens 130, a polarized lens 132, or one or more other lenses. In some embodiments, the focus lens 130 is configured to channel light, which impinges upon the focus lens 130, towards at least one of the polarized lens 132 or the optical filter 134. In some embodiments, in comparison with embodiments without the focus lens 130, implementing the reflection detector 124 with the focus lens 130 provides for more light of the reflection signal 118 reaching at least one of the optical filter 134 or the light sensor 136, thereby improving an accuracy of a signal generated by the light sensor 136. In some embodiments, the polarized lens 132 is configured to optically polarize photons of light impinging upon the polarized lens 132, and conduct polarized photons to the optical filter 134. In some embodiments, in comparison with embodiments without the polarized lens 132, implementing the reflection detector 124 with the polarized lens 132 provides for a higher resolution of a signal generated by the light sensor 136.

In some embodiments, the optical filter 134 includes at least one of a bandpass filter or other type of filter. The optical filter 134 is configured to block light that has a wavelength outside a defined range of wavelengths 128 and provide filtered light, from the reflection signal 118, which has a wavelength within the defined range of wavelengths 128. Accordingly, light having a wavelength outside the defined range of wavelengths 128 is at least one of absorbed, filtered, or not transmitted to the light sensor 136, whereas light having a wavelength within the defined range of wavelengths 128 passes through the optical filter 134 to the light sensor 136. The defined range of wavelengths 128 ranges from a wavelength w1 to a wavelength w2. Accordingly, light with a wavelength under the wavelength w1 or over the wavelength w2 is blocked by the optical filter 134.

In some embodiments, the defined range of wavelengths 128 includes a wavelength w3 equal to half of a light signal wavelength of the light signal 108 generated by the ring light source 116. The light signal wavelength of the light signal 108 is equal to a wavelength of the first harmonic light 120 of the reflection signal 118. Accordingly, the second harmonic light 122, which has the wavelength w3 equal to half of the light signal wavelength, passes through the optical filter 134 to the light sensor 136. In some embodiments, the wavelength w2, corresponding to an upper limit of the defined range of wavelengths 128, is smaller than the light signal wavelength. Accordingly, the first harmonic light 120 in the reflection signal 118 is blocked by the optical filter 134 and is not transmitted to the light sensor 136. In some embodiments, the wavelength w1, corresponding to a lower limit of the defined range of wavelengths 128, is larger than half of the wavelength w3, such that the optical filter 134 blocks at least one of third harmonic light, fourth harmonic light, etc. within the reflection signal 118.

In an embodiment, for example, the light signal wavelength of the light signal 108 is about 850 nanometers, and thus the wavelength w3 of the second harmonic light 122 is about 425 nanometers. In some embodiments, the wavelength w2, corresponding to the upper limit of the defined range of wavelengths 128, is equal to a value larger than 425 nanometers and smaller than 850 nanometers. In some embodiments, the wavelength w1, corresponding to the lower limit of the defined range of wavelengths 128, is equal to a value larger than 212.5 nanometers and smaller than 425 nanometers. Other values of the light signal wavelength, the wavelengths w1, w2, and w3 are within the scope of the present disclosure.

Thus, in accordance with some of the embodiments herein, the optical filter 134 provides the second harmonic light 122 to the light sensor 136 while blocking at least one of the first harmonic light 120 or other harmonics from reaching the light sensor 136. Other configurations of the optical filter 134 are within the scope of the present disclosure.

Accordingly, the light sensor 136 is configured to generate an electrical signal based upon the filtered light provided by the optical filter 134. In some embodiments, the electrical signal is indicative of a measure of intensity of the filtered light. In some embodiments, the measure of intensity of the filtered light corresponds to a measure of intensity of the second harmonic light 122, such as due, at least in part, to the filtered light including the second harmonic light 122 and light other than the second harmonic light 122 being filtered out of the filtered light by the optical filter 134. In some embodiments, the light sensor 136 includes an array of photodiodes 138. A photodiode of the array of photodiodes 138 is configured to produce current of the electrical signal, wherein an amount of the current produced by the photodiode depends upon an amount of photons that reach the photodiode. The photons are at least one of sensed, detected, or converted to electrons by the photodiode. In some embodiments, the electrical signal generated by the light sensor 136 having at least one of a higher voltage or a higher current indicates a higher measure of intensity of the filtered light. In some embodiments, the ring light source 116 and the reflection detector 124 is integrated as a detection device 101 for detecting electrostatic field strength. That is, the detection device 101 may be an electrostatic field detection device.

In some embodiments, the apparatus 102 includes a processor 140 configured to determine, based upon the electrical signal generated by the light sensor 136, a plurality of measures of electrostatic field strength at the surface 106 of the target object 104. In some embodiments, a measure of electrostatic field strength of the plurality of measures of electrostatic field strength corresponds to at least one of a measure of electrostatic charge accumulation, a voltage level, an electrostatic field strength amplitude, or other measure.

In some embodiments, the plurality of measures of electrostatic field strength are associated with a plurality of points or regions of the surface 106 of the target object 104. A first measure of electrostatic field strength of the plurality of measures of electrostatic field strength is associated with a first point or region of the surface 106, and corresponds to at least one of a measure of electrostatic charge accumulation associated with the first point or region, a voltage level associated with the first point or region, an electrostatic field strength amplitude associated with the first point or region, or other measure associated with the first point or region. A second measure of electrostatic field strength of the plurality of measures of electrostatic field strength is associated with a second point or region of the surface 106, and corresponds to at least one of a measure of electrostatic charge accumulation associated with the second point or region, a voltage level associated with the second point or region, an electrostatic field strength amplitude associated with the second point or region, or other measure associated with the second point or region.

In some embodiments, the plurality of measures of electrostatic field strength are associated with a scanning cycle in which the ring light source 116 scans the light signal 108 across the plurality of points or regions of the surface 106 of the target object 104. At least one of the first measure of electrostatic field strength is generated based upon a reflection of the light signal 108 upon the first point or region during the scanning cycle, the second measure of electrostatic field strength is generated based upon a reflection of the light signal 108 upon the second point or region during the scanning cycle, etc.

In some embodiments, the first measure of electrostatic field strength is generated based upon a first measure of intensity indicated by the electrical signal generated by the light sensor 136. The first measure of intensity is generated based upon filtered light filtered by the optical filter 134 from first light of the reflection signal 118, wherein the first light of the reflection signal 118 includes light, of the light signal 108, reflected by the first point or region of the surface 106 of the target object 104. In some embodiments, the processor 140 performs one or more operations, such as one or more mathematical operations, using the first measure of intensity to determine the first measure of electrostatic field strength. The first measure of electrostatic field strength is a function of at least one of the first measure of intensity, a distance between the reflection detection device 124 and the first point or region of the surface 106, or other value.

In some embodiments, the second measure of electrostatic field strength is generated based upon a second measure of intensity indicated by the electrical signal generated by the light sensor 136. The second measure of intensity is generated based upon filtered light filtered by the optical filter 134 from second light of the reflection signal 118, wherein the second light of the reflection signal 118 includes light, of the light signal 108, reflected by the second point or region of the surface 106 of the target object 104. In some embodiments, the processor 140 performs one or more operations, such as one or more mathematical operations, using the second measure of intensity to determine the second measure of electrostatic field strength. The second measure of electrostatic field strength is a function of at least one of the second measure of intensity, a distance between the reflection detection device 124 and the second point or region of the surface 106, or other value.

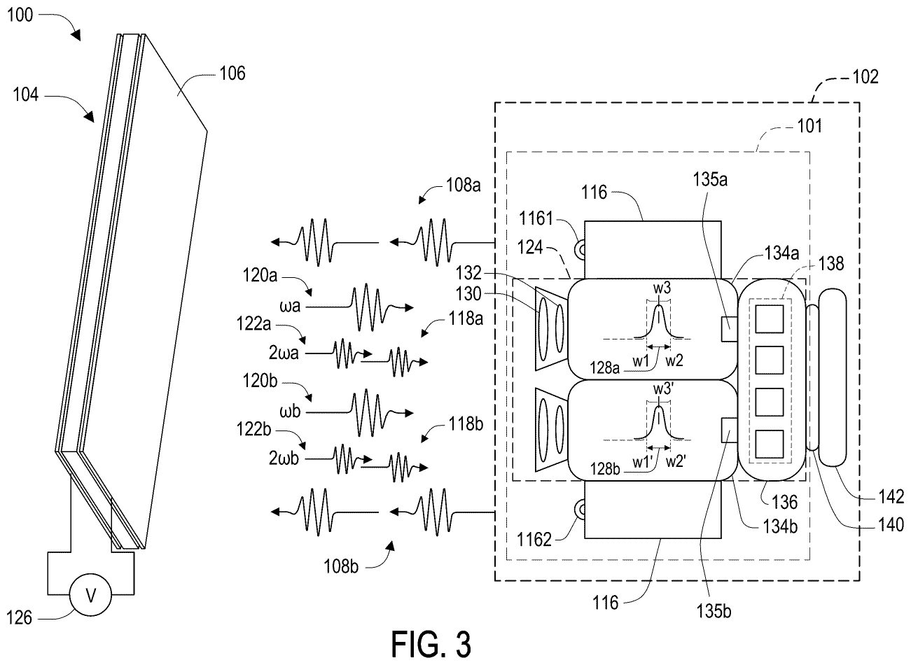

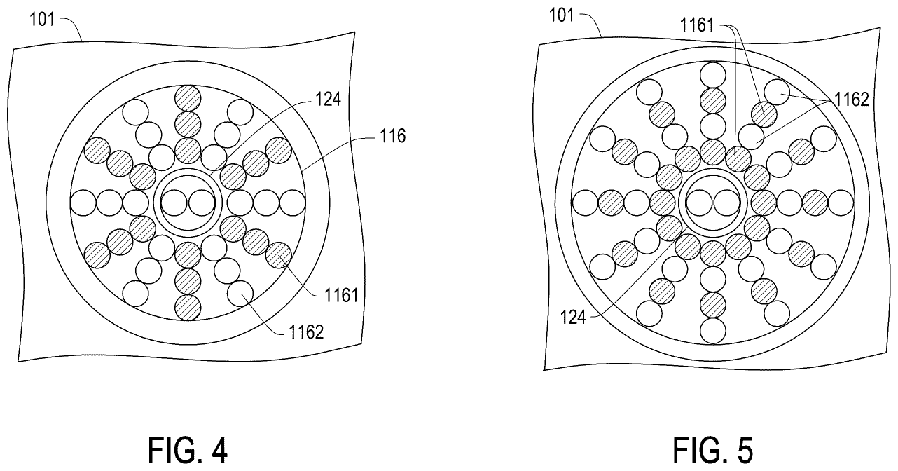

FIG. 3 illustrates a schematic view of an apparatus, in accordance with some embodiments. FIG. 4 illustrates a partial enlarged view of an apparatus, in accordance with some embodiments. The ring light sources 116 shown in FIG. 3 to FIG. 5 contain many features same as or similar to the ring light sources 116 disclosed in the earlier embodiments. For purpose of clarity and simplicity, detail description of same or similar features may be omitted, and the same or similar reference numbers denote the same or like components. With now reference to both FIG. 3 and FIG. 4, in the embodiment, the ring light source 116 includes a plurality of first photodiodes 1161 and a plurality of second photodiodes 1162. The first photodiodes 1161 are configured to emit a first light signal 108a with a first wavelength to the target object 104 and the second photodiodes 1162 are configured to emit a second light signal 108b with a second wavelength to the target object 104. The first wavelength of the first light signal 108a is different from the second wavelength of the second light signal 108b for detecting the electrostatic field strengths of different materials at the surface 106 of the target object 104. In the present embodiment, the ring light source 116 is a laser source in a ring shape. Accordingly, the first photodiodes 1161 are laser diodes configured to emit the first laser signal 108a with the first wavelength and the second photodiodes 1162 are laser diodes configured to emit the second laser signal 108a with the second wavelength. However, the disclosure is not limited thereto. In other embodiments, the ring light source 116 may be a laser source, a radio source, ultraviolet source, visible light source, near infrared light source, ultra-sonic wave source, etc. The ring light source 116 may adopt LiDAR (Light Detection And Ranging), radar, ultra-sonic wave to measure of a characteristic of the surface of the target object 104. The characteristic includes an electrostatic field strength at the surface 106 of the target object 104, a dimension of the surface 106 of the target object 104, or a distance from the reflection detector 124 to the surface 106 of the target object 104. The reflection detector 124 is disposed within and surrounded by the ring light source 116 and configured to receive a first reflection signal 118a of the first light signal 108a and a second reflection signal 118b of the second light signal 108b, which are reflected by the surface 106 of the target object 104 and generate a first electrical signal and a second electrical signal based upon the first reflection signal 118a and the second reflection signal 118b respectively.

In some embodiments, a power of the first light signal 108a emitted by the first photodiodes 1161 is about equal to a power of the second light signal 108b emitted by the second photodiodes 1162, such that the light signal 108a, 108b impinge upon the surface 106 of the target object 104 are about the same, and the filtered light, filtered from the reflection signal 108a, 108b, reaching the light sensor 136 is about the same. In one embodiment, a number of the first photodiodes 1161 is equal to a number of the second photodiodes 1162. Referring to FIG. 3 and FIG. 4, in the embodiment, the first photodiodes 1161 and the second photodiodes 1162 are arranged alternately around the ring light source 116. In detail, the first photodiodes 1161 are arranged radially in a plurality of columns, and the second photodiodes 1162 are also arranged radially in a plurality of columns. The columns of first photodiodes 1161 and the columns of second photodiodes 1162 are arranged alternately around the ring light source 116. Accordingly, the first photodiodes 1161 and the second photodiodes 1162 are distributed evenly across the ring light source 116, and the power (in total) of the first light signal 108a emitted by the first photodiodes 1161 is equal to a power (in total) of the second light signal 108b emitted by the second photodiodes 1162.

Referring to FIG. 3 and FIG. 5, in the embodiment, the first photodiodes 1161 are arranged as a plurality of rings surrounding the reflection detector 124 at the center of the ring light source 116, and the second photodiodes 1161 are also arranged as a plurality of rings surrounding the reflection detector 124 at the center. The rings of first photodiodes 1161 and the rings of second photodiodes 1162 are arranged alternately and concentrically for surrounding the reflection detector 124 at the center of the ring light source 116. Accordingly, the first photodiodes 1161 and the second photodiodes 1162 are distributed evenly across the ring light source 116. In the embodiments, the number of the first photodiodes 1161 may not be necessarily equal to the number of the second photodiodes 1162, but the power of the first light signal 108a emitted by the first photodiodes 1161 is equal to the power of the second light signal 108b emitted by the second photodiodes 1162. In other embodiments, the power of the first light signal 108a emitted by the first photodiodes 1161 may not be equal to the power of the second light signal 108b emitted by the second photodiodes 1162, as long as the processor 140 adjusts the results according to the power difference between the first light signal 108a and the second light signal 108b. It is noted that, in the embodiment of FIG. 3 to FIG. 5, two sets of photodiodes 1161, 1162 for emitting two light signals with different wavelengths are illustrated; however, more than two sets of photodiodes may be provided in the ring light source 116 for emitting more than two light signals with more than two different wavelengths in order to detecting the electrostatic field strength of more than two different materials at the target object 104.

Referring to FIG. 3, in some embodiments, the ring light source 116 performs light scanning cycles in which the ring light source 116 emits the first light signal 108a and the second light signal 108b to scan across the target object 104 in at least one of a horizontal direction or a vertical direction. The ring light source 116 is in a ring shape and configured to surround the reflection detector 124 therein. The first photodiodes 1161 and the second photodiodes 1162 are distributed evenly over the ring light source 116 such that the reflection detector 124 is surrounded by the first photodiodes 1161 and the second photodiodes 1162. Accordingly, both the first light signal 108a emitted by the first photodiodes 1161 and the second light signal 108b emitted by the second photodiodes 1162 can impinge upon the surface 106 of the target object 104 more evenly, so that the reflection signal 118a, 118b reflected by the surface 106 of the target object 104 can be received by the reflection detector 124 more evenly.

In some embodiments, the reflection detector 124 is configured to receive the first reflection signal 118a and the second reflection signal 118b reflected by the surface 106 of the target object 104. Take the reflection signal 118a for example, the reflection signal 118a includes first harmonic light 120a “ωₐ” and second harmonic light 122a “2ωₐ”. The second harmonic light 122a is generated via second-harmonic generation (also called frequency doubling) that occurs when the light of the light signal 108a is reflected by the surface 106 of the target object 104. As a result of the second-harmonic generation, two photons of the light of the light signal 108a are combined to generate a new photon in the reflection signal 118a with about twice the energy of the two photons, about twice the frequency of the two photons, and about half the wavelength of the two photons. Similarly, the reflection signal 118b includes first harmonic light 120b “ω_{b}” and second harmonic light 122a “2ω_{b}”, and two photons of the light of the light signal 108b are combined to generate a new photon in the reflection signal 118b with about twice the energy of the two photons, about twice the frequency of the two photons, and about half the wavelength of the two photons.

That is, the reflected wavelengths of the second harmonic light 122a in the reflection signal 118a is about half of the (initial) wavelength of the first harmonic light 120a in the reflection signal 118a. Similarly, the reflected wavelengths of the second harmonic light 122b in the reflection signal 118b is about half of the (initial) wavelength of the first harmonic light 120b in the reflection signal 118b. In addition, since the wavelength of the first light signal 108a is different from the wavelength of the second light signal 108b, the wavelength of the first harmonic light 120a from the first light signal 108a is different from the wavelength of the first harmonic light 120b from the second light signal 108b. Accordingly, the wavelengths of the second harmonic light 122a from the first light signal 108a is different from the wavelength of second harmonic light 122b from the second light signal 108b.

In some embodiments, the reflection detector 124 includes a first optical filter 134a and a second optical filter 134a. The first optical filter 134a is configured to filter the first reflection signal 118a and provide a first filtered light, from the first reflection signal 118a, with a wavelength within a first defined range of wavelengths 128a. The second optical filter 134b is configured to filter the second reflection signal 118b and provide a second filtered light, from the second reflection signal 118b, with a wavelength within a second defined range of wavelengths 128b. Accordingly, light having a wavelength outside the defined range of wavelengths 128a and 128b is at least one of absorbed, filtered, or not transmitted to the light sensor 136, whereas light having a wavelength within the defined range of wavelengths 128a, 128b passes through the corresponding optical filters 134a, 134b to the light sensor 136. The defined range of wavelengths 128a ranges from a wavelength w1 to a wavelength w2, and the defined range of wavelengths 128b ranges from a wavelength w1′ to a wavelength w2′.

In some embodiments, the defined range of wavelengths 128a includes a wavelength w3 equal to half of a light signal wavelength of the first light signal 108a generated by the first photodiodes 1161, while the defined range of wavelengths 128b includes a wavelength w3′ equal to half of a light signal wavelength of the second light signal 108b generated by the second photodiodes 1162. In one embodiment, the light signal wavelength of the light signal 108a is equal to a wavelength of the first harmonic light 120a of the reflection signal 118a. Accordingly, the second harmonic light 122a, which has the wavelength w3 equal to half of the light signal wavelength, passes through the first optical filter 134a to the light sensor 136. In some embodiments, the wavelength w2, corresponding to an upper limit of the defined range of wavelengths 128a, is smaller than the light signal wavelength. Accordingly, the first harmonic light 120a in the reflection signal 118a is blocked by the first optical filter 134a and is not transmitted to the light sensor 136. In some embodiments, the wavelength w1, corresponding to a lower limit of the defined range of wavelengths 128a, is larger than half of the wavelength w3, such that the first optical filter 134a blocks at least one of third harmonic light, fourth harmonic light, etc. within the reflection signal 118a.

Similarly, the second harmonic light 122b in the reflection signal 118b passes through the second optical filter 134b to the light sensor 136, and the first harmonic light 120b in the reflection signal 118b is blocked by the second optical filter 134b and is not transmitted to the light sensor 136. In addition, the second optical filter 134b blocks at least one of third harmonic light, fourth harmonic light, etc. within the reflection signal 118b. Thus, in accordance with some of the embodiments herein, the second optical filter 134b provides the second harmonic light 122a, 122b to the light sensor 136 while blocking at least one of the first harmonic light 120a, 120b or other harmonics from reaching the light sensor 136. Other configurations of the optical filters are within the scope of the present disclosure.

In some embodiments, the reflection detector 124 further includes a first optical sensor 135a and a second optical sensor 135b. The first optical sensor 135a is configured to receive the first filtered light, e.g., second harmonic light 122a, passing through the first optical filter 134a and having the wavelength within the defined range of wavelengths 128a. The second optical sensor 135b is configured to receive the second filtered light, e.g., second harmonic light 122b, passing through the second optical filter 134b and having the wavelength within the defined range of wavelengths 128b.

In some embodiments, the reflection detector 124 further includes one or more lenses 130, 132 configured to conduct the first reflection signal 118a to the first optical filter 134a and conduct the second reflection signal 118b to the second optical filter 134b. The one or more lenses includes at least one of a focus lens 130, a polarized lens 132, or one or more other lenses. In some embodiments, the focus lens 130 is configured to channel light, which impinges upon the focus lens 130, towards at least one of the polarized lens 132 or the optical filters 134a, 134b. In some embodiments, in comparison with embodiments without the focus lens 130, implementing the reflection detector 124 with the focus lens 130 provides for more light of the reflection signal 118a, 118b reaching the corresponding optical filters 134a and 134b, thereby improving an accuracy of a signal generated by the light sensor 136. In some embodiments, the polarized lens 132 is configured to optically polarize photons of light impinging upon the polarized lens 132, and conduct polarized photons to the corresponding optical filters 134a and 134b. In some embodiments, in comparison with embodiments without the polarized lens 132, implementing the reflection detector 124 with the polarized lens 132 provides for a higher resolution of a signal generated by the light sensor 136.

Accordingly, the light sensor 136 is configured to generate a first electrical signal and a second electrical signal based upon the filtered light provided by the optical filters 134a, 134b. In some embodiments, the electrical signal is indicative of a measure of intensity of the filtered light. In some embodiments, the measure of intensity of the filtered light corresponds to a measure of intensity of the second harmonic light 122a and 122b, such as due, at least in part, to the filtered light including the second harmonic light 122a and 122b and light other than the second harmonic light 122a and 122b being filtered out of the filtered light by the optical filters 134a, 134b. In some embodiments, the light sensor 136 includes an array of photodiodes 138. A photodiode of the array of photodiodes 138 is configured to produce current of the electrical signals, wherein an amount of the current produced by the photodiode depends upon an amount of photons that reach the photodiode. The photons are at least one of sensed, detected, or converted to electrons by the photodiode. In some embodiments, the first electrical signal and the second electrical signal generated by the light sensor 136 having at least one of a higher voltage or a higher current indicates a higher measure of intensity of the filtered light.

In some embodiments, the processor 140 generates an electrostatic field strength map based upon the plurality of measures of electrostatic field strength. The electrostatic field strength map is indicative of the plurality of measures of electrostatic field strength. In some embodiments, the electrostatic field strength map is indicative of the plurality of points or regions, of the surface 106 of the target object 104, associated with the plurality of measures of electrostatic field strength. In some embodiments, the electrostatic field strength map includes an array of values, wherein a value in the array is associated with a point or region of the surface 106 of the target object 104, and is indicative of a measure of electrostatic field strength associated with the point or region. In some embodiments, a first value of the array of values is associated with the first point or region of the surface 106, and is indicative of the first measure of electrostatic field strength. A second value of the array of values is associated with the second point or region of the surface 106, and is indicative of the second measure of electrostatic field strength.

In some embodiments, the electrostatic field strength map includes an electrostatic field strength image. In some embodiments, the electrostatic field strength image is indicative of the plurality of measures of electrostatic field strength, and the plurality of points or regions, of the surface 106 of the target object 104, associated with the plurality of measures of electrostatic field strength. In some embodiments, the processor 140 includes an image signal processor configured to generate the electrostatic field strength image. In some embodiments, the electrostatic field strength image is a color-coded image, where a color of a pixel of the electrostatic field strength image is indicative of a measure of electrostatic field strength associated with a point, of the surface 106 of the target object 104, corresponding to the pixel.

In some embodiments, the processor 140 determines a plurality of pixel colors of the electrostatic field strength image based upon the plurality of measures of electrostatic field strength. In some embodiments, the processor 140 determines a first pixel color, of the plurality of pixel colors, based upon the first measure of electrostatic field strength associated with the first point or region. The processor 140 generates one or more first pixels, of the electrostatic field strength image, according to the first pixel color. At least one of a shade, tint, tone, color, etc. of the first pixel color is based upon the first measure of electrostatic field strength. The one or more first pixels of the electrostatic field strength image correspond to the first point or region of the surface 106.

In some embodiments, the processor 140 determines a second pixel color, of the plurality of pixel colors, based upon the second measure of electrostatic field strength associated with the second point or region. The processor 140 generates one or more second pixels, of the electrostatic field strength image, according to the second pixel color. At least one of a shade, tint, tone, color, etc. of the second pixel color is based upon the measure of electrostatic field strength. The one or more second pixels of the electrostatic field strength image correspond to the second point or region of the surface 106.

In some embodiments, if the first measure of electrostatic field strength is different than the second measure of electrostatic field strength, at least one of a shade, tint, tone, color, etc. of the first pixel color is different than at least one of a shade, tint, tone, color, etc. of the second pixel color. In an embodiment, at least one of a first range of measures of electrostatic field strength correspond to red, a second range of measures of electrostatic field strength correspond to blue, a third range of measures of electrostatic field strength correspond to purple, etc. In some embodiments, the first range of measures of electrostatic field strength are associated with varying shades, tints, tones, etc. of red, wherein a higher measure of electrostatic field strength in the first range corresponds to a darker or lighter shade, tint, tone, etc. of red than a lower measure of electrostatic field strength in the first range.

In some embodiments, the apparatus 102 includes an image sensor configured to generate a visual image of the target object 104. In some embodiments, the image sensor is part of the processor 140, or is separate from the processor 140. The image sensor includes at least one of a charge coupled device (CCD) image sensor, a complementary metal oxide semiconductor (CMOS) image sensor, a contact image sensor (CIS), recording film, or other device. The image sensor generates the visual image to be a visual representation of the target object 104. In some embodiments, the processor 140, such as the image signal processor of the processor 140, generates the electrostatic field strength image based upon the plurality of measures of electrostatic field strength and the visual image. In some embodiments, the processor 140 generates the electrostatic field strength image using the visual image and the plurality of pixel colors determined based upon the plurality of measures of electrostatic field strength, such as by combining the visual image with the plurality of pixel colors to generate the electrostatic field strength image. In some embodiments, the processor 140 modifies the visual image based upon the plurality of pixel colors to generate the electrostatic field strength image. In some embodiments, the electrostatic field strength image is a visual representation of the target object 104 and the plurality of measures of electrostatic field strength.

In some embodiments, the apparatus 102 is positioned facing the target object 104 such that the light signal 108 is emitted towards the target object 104. In some embodiments, at least one of during operation of the target object 104, before the operation of the target object 104, or after the operation of the target object 104, the apparatus 102 determines measures of electrostatic field strength associated with the target object 104, generates electrostatic field strength maps associated with the target object 104, or detects one or more electrostatic events associated with the target object 104. In some embodiments, the target object 104 is a semiconductor fabrication equipment, and the operation of the target object 104 corresponds to a state of the target object 104 in which the target object 104 is actively used to perform one or more operations, such as at least one of conduct fluid through a tube, perform CVD, perform plasma CVD, perform high density plasma CVD, perform surface treatment, perform plasma surface treatment, perform implantation process, perform PVD, perform plasma enhanced PVD, perform etching, perform dry etching, perform wet etching, perform plasma etching, activate a robot arm, etc.

In some embodiments, the target object 104 is used in a facility, such as an industrial facility, in which semiconductor devices are fabricated. In some embodiments, the target object 104 is used to perform one or more semiconductor fabrication acts corresponding to at least a part of a semiconductor fabrication process performed to at least partially fabricate the semiconductor devices. In some embodiments, the one or more semiconductor fabrication acts correspond to at least one of front-end-of-line (FEOL) fabrication, back-end-of-line (BEOL) fabrication, semi-completed product fabrication, or other types of semiconductor fabrication. In some embodiments, the target object 104 corresponds to equipment that directly processes the semiconductor devices. In some embodiments, the target object 104 corresponds to equipment that manages at least one of a temperature, an air pressure, a humidity, etc. of the facility. In some embodiments, the target object 104 corresponds to equipment, such as tubes, valves, manifolds, power lines, etc., that is configured to supply tools in the facility with resources including at least one of gas, liquid, heat, energy, etc., wherein the resources are used by the tools to perform semiconductor fabrication acts. In some embodiments, the semiconductor devices include at least one of transistors, gate-all-around field-effect-transistors (GAA FETs), metal-oxide-semiconductor field-effect-transistors (MOSFETs), fin field-effect transistors (finFETs), two-dimensional (2D) devices, or other types of semiconductor devices.

In some embodiments, the apparatus 102 is in a fixed position, such as coupled to a fixed position mount. In some embodiments, the apparatus 102 is coupled to a mobile or portable device or vehicle. For example, the apparatus 102 may be integrated with a mobile device, such as an overhead hoist transport (OHT), automatic material handling system (AMHS), unmanned aerial vehicle (UAV), a robot arm, or the like, in the industrial facility where semiconductor devices are fabricated. In some embodiments, the apparatus 102 is rotatable around an axis, such as coupled to a motor that automatically controls an angular position of the apparatus 102 with respect to the axis. In some embodiments, a scope for which the apparatus 102 at least one of determines the plurality of measures of electrostatic field strength or generates the electrostatic field strength map is adjustable. In some embodiments, increasing the scope corresponds to zooming-out such that at least one of the plurality of measures of electrostatic field strength or the electrostatic field strength map cover a larger area. In some embodiments, decreasing the scope corresponds to zooming-in such that at least one of the plurality of measures of electrostatic field strength or the electrostatic field strength map cover a smaller area.

Embodiments are contemplated in which at least some of the apparatus 102, such as at least one of the ring light source 116 or the reflection detector 124, is implemented in an inspection device that can be inserted through a cavity, such as in an endoscopy-like fashion. In some embodiments, the inspection device includes merely some of the apparatus 102, and the inspection device is smaller than an implementation of the entirety of the apparatus 102 in a single package, and can thus be inserted through smaller openings and/or be positioned in smaller spaces than the single package. In some embodiments, the inspection device is positioned within the target object 104, such as at least one of a process chamber, a valve manifold box, a tube, etc., such that at least one of measures of electrostatic field strength, electrostatic field strength maps, or electrostatic events are determined from within the target object 104. Embodiments are contemplated in which the entirety of the apparatus 102 is implemented in a single package.

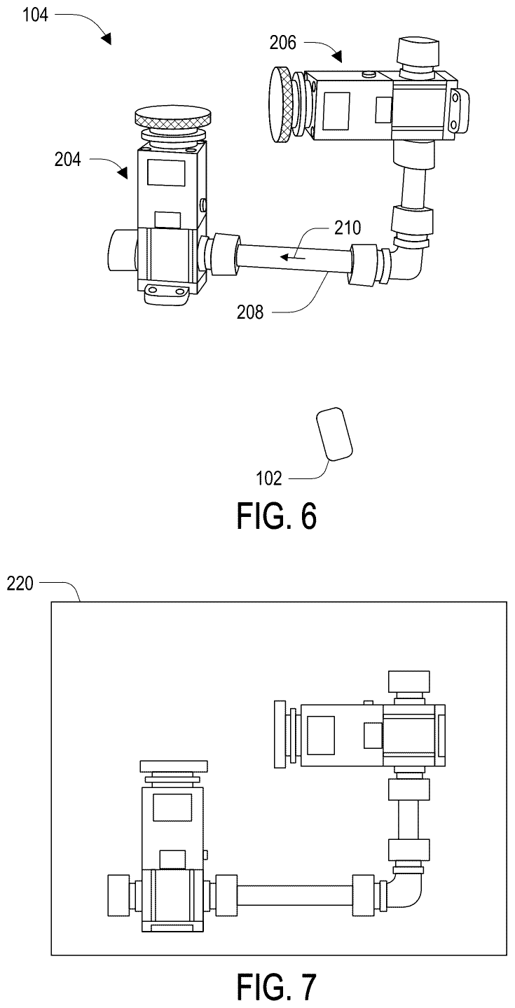

FIG. 6 to FIG. 9 illustrate generation of the electrostatic field strength image using the apparatus 102, according to some embodiments in which the target object 104 includes a first valve 204, a second valve 206, and a tube 208, such as an insulated tube configured to conduct fluid 210 including at least one of liquid or gas. FIG. 6 illustrates a perspective view of the apparatus 102 and the target object 104, according to some embodiments. In some embodiments, the apparatus 102 is positioned facing the target object 104, and emits the light signal 108 (shown in FIG. 1) towards the target object 104. The first valve 204 is at least one of a manual valve, an automatic valve, or other type of valve. The second valve 206 is at least one of a manual valve, an automatic valve, or other type of valve. In some embodiments, the fluid 210 is conducted from the second valve 206, through the tube 208, to the first valve 204.

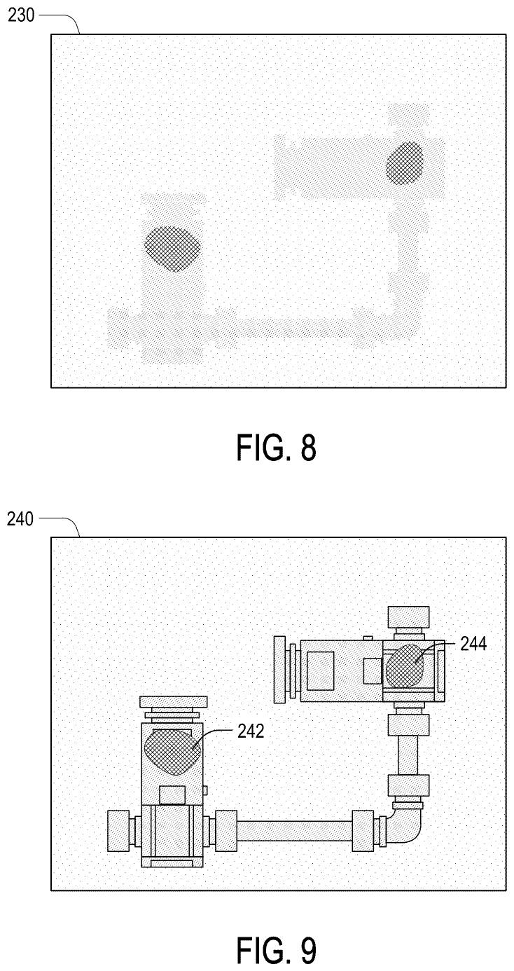

FIG. 8 illustrates the visual image (shown with reference number 220) of the target object 104 generated using the image sensor of the apparatus 102, according to some embodiments. The visual image 220 includes a visual representation of the target object 104. FIG. 8 illustrates a representation 230 of the plurality of pixel colors determined based upon the plurality of measures of electrostatic field strength, according to some embodiments.

FIG. 9 illustrates the electrostatic field strength map generated by the apparatus 102, according to some embodiments in which the electrostatic field strength map includes an electrostatic field strength image 240. In some embodiments, the processor 140 combines the visual image 220 (shown in FIG. 7) with the representation 230 of the plurality of pixel colors (shown in FIG. 8) to generate the electrostatic field strength image 240 (shown in FIG. 9). In some embodiments, the processor 140 modifies the visual image 220, based upon the plurality of pixel colors, to generate the electrostatic field strength image 240. In some embodiments, the electrostatic field strength image 240 includes a visual representation of the target object 104 and the plurality of measures of electrostatic field strength.

Referring to FIG. 3 and FIG. 6, in one embodiments, a first material of a first component (e.g., the first valve 204) of the first target object 104 is different from a second material of a second component (e.g., the second valve 206) of the target object 104, the first wavelength of first light signal 108a and the second wavelength of the second light signal 108b can be predetermined corresponding to the material of the first component and the material of the second component based on the corresponding material parameters such as geometry, physical properties and laser absorption. Different materials react to different laser wavelength. In general, the second harmonic light 122a and 122b is proportional to the electrostatic field strength, and the electrostatic field strength is inversely proportional to wavelength of the light signal 108a, 108b and dielectric constant of the target object 104. That is, the light signal 108a, 108b with greater wavelength can be chose to measure the electrostatic field strength of a material with greater dielectric constant. For example, the first material includes Buckminsterfullerene, known as formula C₆₀, (dielectric constant thereof about 4), and the first wavelength of first light signal 108a for measuring the electrostatic field strength of the first material may be about 1000 nm. The second material includes polyimide (dielectric constant thereof about 3 to 4), and the second wavelength of second light signal 108a for measuring the electrostatic field strength of the second material thereof may be about 900 nm. In one embodiment, the second material includes Perfluoroalkoxy alkane (PFA) (dielectric constant thereof about 2.1), and the second wavelength of second light signal 108a for measuring the electrostatic field strength of the second material thereof may be about 850 nm. However, the disclosure is not limited thereto.

In one embodiment, the first light signal 108a and the second light signal 108b may be emitted simultaneously for measuring the electrostatic field strength of the first material and the second material at the same time, and the electrostatic field strength map including an electrostatic field strength image 240 for both the first component 204 and the second component 206 is generated. In other embodiment, the first light signal 108a and the second light signal 108b may be emitted successively (not simultaneously, but with time delay) for measuring the electrostatic field strength of the first material and the second material in turns. For example, the first light signal 108a may be emitted by the first photodiodes 1161 first for measuring the electrostatic field strength of the first material, and then the second light signal 108b may be emitted by the second photodiodes 1162 for measuring the electrostatic field strength of the second material. Then, the electrostatic field strength map including the electrostatic field strength image 240 for both the first component 204 and the second component 206 is generated.

In some embodiments, the electrostatic field strength image 240 (shown in FIG. 9) is displayed via a display 142 (shown in FIG. 1 and FIG. 3) of the apparatus 102. In some embodiments, the processor 140 updates the display 142 to display an updated and/or current electrostatic field strength image. The processor 140 updates the display 142 at least one of periodically, continuously, or in response to generating an updated and/or current electrostatic field strength image based upon at least one of updated and/or current measures of electrostatic field strength or an updated and/or current visual image generated using the image sensor. In accordance with some embodiments, an electrostatic field strength image displayed via the display 142 is a real-time representation of measures of electrostatic field strength of the target object 104. Embodiments are contemplated in which the display 142 is separate from the apparatus 102, and is controlled to display the electrostatic field strength image 240 at least one of wirelessly or over a physical connection.

In some embodiments, the processor 140 detects an electrostatic event based upon the plurality of measures of electrostatic field strength. In some embodiments, the electrostatic event is detected based upon the electrostatic field strength map, such as the electrostatic field strength image 240. In some embodiments, the electrostatic event corresponds to at least one of an accumulation of electrostatic charge, an electrostatic field hotspot, or a potential ESD event on the target object 104. If the electrostatic event is not detected or addressed, the electrostatic event can cause damage to the target object 104 by at least one of ESD, arcing, micro-arcing, or other event.

In some embodiments, the processor 140 detects the electrostatic event based upon a determination that one or more measures of electrostatic field strength, of the plurality of measures of electrostatic field strength, associated with one or more points or regions of the surface 106 of the target object 104 exceed a threshold measure of electrostatic field strength. In some embodiments, the electrostatic event is determined to be associated with the one or more points or regions of the surface 106 of the target object 104. In some embodiments, the processor 140 detects the electrostatic event based upon a determination that an area covered by the one or more points or regions exceeds a threshold size. In some embodiments, the one or more measures of electrostatic field strength exceeding the threshold measure of electrostatic field strength indicates an increased likelihood of an event occurring, at the one or more points or regions of the surface 106, that can cause damage to the target object 104, such as at least one of ESD, arcing, micro-arcing, or other event.

In some embodiments, the processor 140 detects the electrostatic event based upon a determination that a change in electrostatic field strength, at one or more points or regions of the surface 106 of the target object 104, exceeds a threshold change in electrostatic field strength. In some embodiments, the change in electrostatic field strength is determined based upon one or more first measures of electrostatic field strength, of the plurality of measures of electrostatic field strength, associated with the one or more points or regions of the surface 106 and one or more second measures of electrostatic field strength, associated with the one or more points or regions of the surface 106, previously determined by the apparatus 102. In some embodiments, the change in electrostatic field strength is determined based upon a difference between a measure of electrostatic field strength of the one or more first measures of electrostatic field strength and a measure of electrostatic field strength of the one or more second measures of electrostatic field strength. In some embodiments, the change in electrostatic field strength corresponds to an increase in electrostatic field strength at the one or more points or regions. In some embodiments, the change in electrostatic field strength exceeding the threshold change in electrostatic field strength indicates an increased likelihood of an event occurring, at the one or more points or regions of the surface 106, that can cause damage to the target object 104, such as at least one of ESD, arcing, micro-arcing, or other event.

In some embodiments, the processor 140 detects the electrostatic event based upon a determination that one or more pixels, of the electrostatic field strength image 240, associated with one or more points or regions of the surface 106 of the target object 104 are one or more colors of a defined set of colors associated with electrostatic events. In some embodiments, the electrostatic event is determined to be associated with the one or more points or regions of the surface 106 of the target object 104. In some embodiments, the computer 140 detects the electrostatic event based upon at least one of a determination that the one or more pixels that are the one or more colors have a pixel density that exceeds a threshold pixel density or a determination that a quantity of the one or more pixels exceed a threshold quantity. In some embodiments, the one or more pixels at least one of being the one or more colors of the defined set of colors, having the pixel density that exceeds the threshold pixel density, or having the quantity that exceeds the threshold quantity indicates an increased likelihood of an event occurring, at the one or more points or regions of the surface 106, that can cause damage to the target object 104, such as at least one of ESD, arcing, micro-arcing, or other event.

In some embodiments, the processor 140 detects the electrostatic event based upon identification of a change in pixel color of one or more pixels associated with one or more points or regions of the surface 106 of the target object 104. In some embodiments, the change in pixel color of the one or more pixels is determined by comparing the electrostatic field strength image 240 and a second electrostatic field strength image previously generated by the apparatus 102. In some embodiments, based upon the one or more pixels associated with the change in pixel color, the electrostatic event is determined to be associated with the one or more points or regions of the surface of the target object 104. In some embodiments, the one or more pixels associated with the one or more points or regions undergoing the change in pixel color from the second electrostatic field strength image to the electrostatic field strength image 240 indicates an increased likelihood of an event occurring, at the one or more points or regions of the surface 106, that can cause damage to the target object 104, such as at least one of ESD, arcing, micro-arcing, or other event.

In some embodiments, the processor 140 detects the electrostatic event based upon a pattern in the electrostatic field strength image 240, such as a pattern of pixels. In some embodiments, the electrostatic field strength image 240 is analyzed to identify the pattern. In some embodiments, the pattern corresponds to a set of pixels in the electrostatic field strength image 240. In some embodiments, the electrostatic event is detected based upon the pattern matching a defined pattern of pixels associated with electrostatic events. In some embodiments, the pattern is compared with a plurality of defined patterns of pixels associated with electrostatic events to determine that the pattern matches the defined pattern of pixels. In some embodiments, comparing the pattern with the defined pattern of pixels includes determining a similarity score representative of a similarity, such as a visual similarity, between the pattern and the defined pattern of pixels. In some embodiments, the pattern is determined to match the defined pattern of pixels based upon a determination that the similarity score exceeds a threshold similarity score. In some embodiments, the pattern matching the defined pattern of pixels indicates an increased likelihood of an event occurring, at the one or more points or regions of the surface 106 corresponding to the set of pixels of the pattern, that can cause damage to the target object 104, such as at least one of ESD, arcing, micro-arcing, or other event.

In some embodiments, electrostatic field strength maps generated by the apparatus 102 are monitored, such as monitored in real-time as the electrostatic field strength maps are generated, to detect the electrostatic event. In some embodiments, the processor 140 detects the electrostatic event based upon detection of an anomalous event. In some embodiments, one or more patterns of electrostatic field strength behavior are identified by monitoring the electrostatic field strength maps. In some embodiments, the one or more patterns are identified by performing pattern recognition. In some embodiments, the one or more patterns correspond to temporal patterns of electrostatic field strength over time that result from operation, such as typical operation, of the target object 104. In some embodiments, the anomalous event is detected based upon identifying a deviation from the one or more patterns. In some embodiments, the deviation from the one or more patterns is associated with one or more points or regions of the surface 106. In some embodiments, the anomalous event indicates an increased likelihood of an event occurring, at the one or more points or regions of the surface 106 associated with the anomalous event, that can cause damage to the target object 104, such as at least one of ESD, arcing, micro-arcing, or other event.

In some embodiments, the processor 140 detects the electrostatic event using a trained machine learning model. In some embodiments, the trained machine learning model is trained using training information including electrostatic field strength maps, such as electrostatic field strength images, generated over a period of time. In some embodiments, the electrostatic field strength maps are retrieved from an electrostatic field strength map data store used to store generated electrostatic field strength maps. In some embodiments, the electrostatic field strength maps are generated by the apparatus 102. In some embodiments, the electrostatic field strength maps are generated in association with at least one of the target object 104 or one or more other components, such as where the electrostatic field strength maps are generated based upon electrostatic field strength measures, determined during the period of time, of at least one of the target object 104 or the one or more other components. In some embodiments, the trained machine learning model includes at least one of an artificial neural network, an artificial intelligence model, a pattern recognition model, a tree-based model, a machine learning model used to perform linear regression, a machine learning model used to perform logistic regression, a decision tree model, a support vector machine (SVM), a Bayesian network model, a k-Nearest Neighbors (k-NN) model, a K-Means model, a random forest model, a machine learning model used to perform dimensional reduction, a machine learning model used to perform gradient boosting, or other machine learning model. In some embodiments, the trained machine learning model is trained to perform electrostatic event detection to detect electrostatic events. In some embodiments, the trained machine learning model performs anomalous event detection to identify anomalous electrostatic field strength events considered to be electrostatic events. In some embodiments, the trained machine learning model performs pattern recognition to identify one or more patterns of measures of electrostatic field strength that result from operation, such as typical operation, of the target object 104, and detects one or more electrostatic events by identifying a deviation from the one or more patterns. In some embodiments, the trained machine learning model is updated, such as updated periodically or continuously, using newly generated electrostatic field strength maps. In some embodiments, electrostatic field strength maps generated by the apparatus 102 are used to update the trained machine learning model in real-time as the electrostatic field strength maps are generated. In some embodiments, training and/or updating the trained machine learning model includes adjusting trainable parameters of the trained machine learning model to increase an accuracy of electrostatic event detection performed using the trained machine learning model.

FIG. 9 illustrates a first electrostatic event 242 and a second electrostatic event 244 detected by the processor 140, according to some embodiments. In some embodiments, the first electrostatic event 242 is detected based upon one or more pixels associated with one or more points or regions corresponding to the first valve 204 (shown in FIG. 6). In some embodiments, the first electrostatic event 242 is detected based upon a determination that the one or more pixels are one or more colors of the defined set of colors associated with electrostatic events. In some embodiments, the first electrostatic event 242 is detected based upon a determination that the one or more pixels are indicative of measures of electrostatic field strength that exceed the threshold measure of electrostatic field strength. In some embodiments, the first electrostatic event 242 is detected based upon a determination that a change in pixel color over time, of the one or more pixels, is indicative of a change in electrostatic field strength that exceeds the threshold change in electrostatic field strength. In some embodiments, the first electrostatic event 242 is detected using the trained machine learning model. In some embodiments, the first electrostatic event 242 is a result of the fluid 210 (shown in FIG. 6), such as high resistance fluid, flowing through at least one of the tube 208 or the first valve 204 and introducing electrostatic charge to the first valve 204.

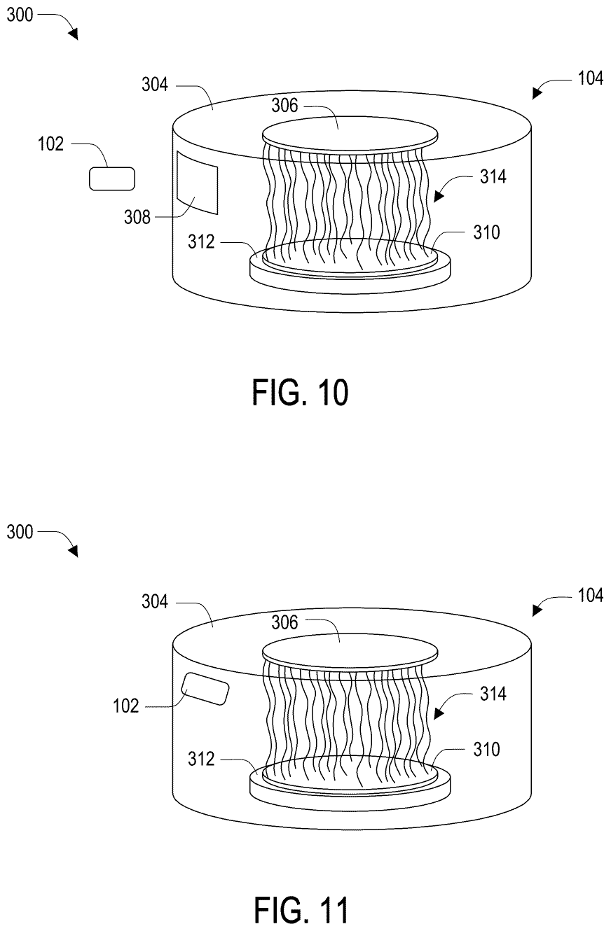

FIG. 10 illustrates a perspective view of an apparatus and a target object, in accordance with some embodiments. In some embodiments, the target object 104 includes at least a portion of semiconductor processing equipment. The semiconductor processing equipment includes at least one of a semiconductor processing chamber 304, a semiconductor wafer 310 (.e.g., substrate, die, etc. and/or device (e.g., transistor, diode, etc.) formed therein, thereon, therefrom, etc. including semiconductor and/or other material(s)), a target 306, a wafer support 312, or one or more other components. In some embodiments, the semiconductor wafer 310 and/or one or more other components are merely associated with the semiconductor processing equipment and thus are not necessarily part of the semiconductor processing equipment (e.g., are merely placed within the semiconductor processing equipment to be processed). In some embodiments, the semiconductor processing equipment includes PVD equipment, CVD equipment, plating equipment, etching equipment, lithography equipment, CMP equipment, equipment that utilizes plasma 314, or other equipment used to process the semiconductor wafer 310 in the semiconductor processing chamber 304. In some embodiments, the apparatus 102 is positioned outside the semiconductor processing chamber 304, and utilizes a window 308 on an outer wall of the semiconductor processing chamber 304 to generate electrostatic field strength maps associated with electrostatic field strength measurements of an interior of the semiconductor processing chamber 304, thereby enabling the apparatus 102 to detect one or more electrostatic events, occurred on the same or different materials, within the semiconductor processing chamber 304. In some embodiments, the one or more electrostatic events include an electrostatic event caused by the plasma 314, such as high-density plasma. In some embodiments, the window 308 is an opening, or is made of a material, such as a transparent material, through which the laser signal 108a, 108b and the reflection signal 118a, 118b can pass. Embodiments are contemplated in which the apparatus 102 generates electrostatic field strength maps associated with electrostatic field strength measurements of an exterior of the semiconductor processing chamber 304, such as the outer wall of the semiconductor processing chamber 304, thereby enabling the apparatus 102 to detect one or more electrostatic events at the exterior of the semiconductor processing chamber 304.

FIG. 11 illustrates a perspective view of the apparatus 102 and the target object 104 including at least a portion of the semiconductor processing equipment, according to some embodiments in which the apparatus 102 is positioned inside the semiconductor processing chamber 304. Accordingly, the apparatus 102 generates electrostatic field strength maps associated with electrostatic field strength measurements of the interior of the semiconductor processing chamber 304, thereby enabling the apparatus 102 to detect one or more electrostatic events within the semiconductor processing chamber 304.

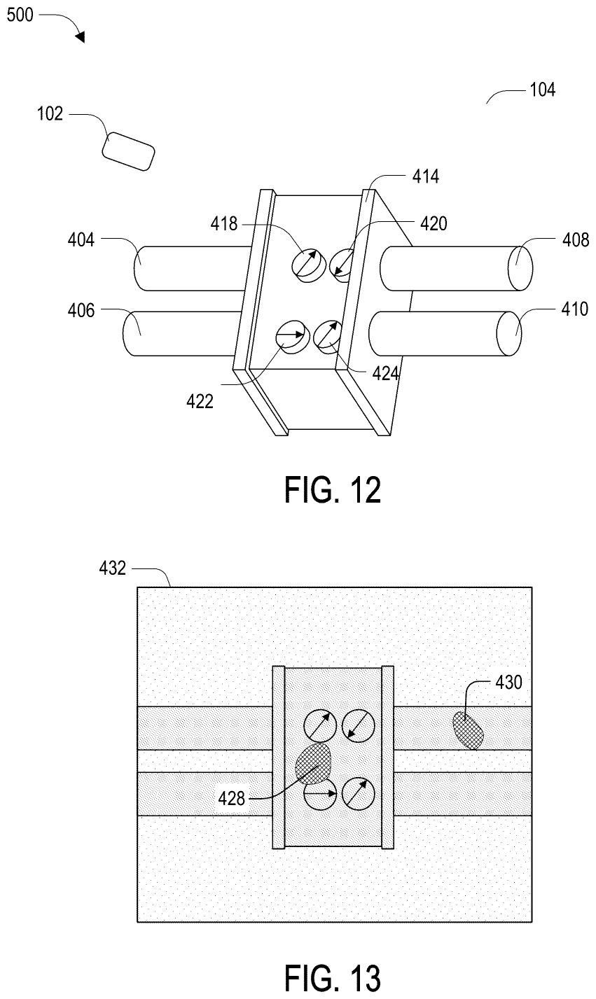

FIG. 12 to FIG. 13 illustrate operation of the apparatus 102, according to some embodiments in which the target object 104 includes at least one of a valve manifold box 414 or one or more tubes coupled to the valve manifold box 414. FIG. 12 illustrates a perspective view of the apparatus 102 and the target object 104, according to some embodiments. In some embodiments, the apparatus 102 is positioned facing the target object 104. In some embodiments, the valve manifold box 414 is configured to distribute, using the one or more tubes, fluid from a source to one or more tools. In some embodiments, the tools use the fluid, including at least one of gas or liquid, for fabricating semiconductor devices. In some embodiments, the one or more tubes include at least one of a tube 404, a tube 406, a tube 408, or a tube 410. In some embodiments, the valve manifold box 414 includes one or more gauges to display measurements, such as pressure measurements, associated with at least one of valves or tubes that are within or coupled to the valve manifold box 414. The one or more gauges include at least one of a gauge 418, a gauge 420, a gauge 422, or a gauge 424.

FIG. 13 illustrates an electrostatic field strength image 432 generated by the apparatus 102, according to some embodiments. Referring to FIG. 12 and FIG. 13, in some embodiments, the electrostatic field strength image 432 is generated using measures of electrostatic field strength across points or regions of the target object 104 including at least one of the valve manifold box 414 or the one or more tubes, such as using one or more of the techniques shown in and/or described with respect to FIG. 6 to FIG. 9. In one embodiment, referring to FIG. 3 and FIG. 12, a first material of a first component (e.g., the valve manifold box 414) is different from a second material of a second component (e.g., the tubes 404-410) of the target object 104. Accordingly, the first wavelength of first light signal 108a and the second wavelength of the second light signal 108b can be predetermined corresponding to the material of the first component and the material of the second component for measuring the electrostatic field strength of the first material and the second material. Then, the electrostatic field strength map including the electrostatic field strength image 432 for both the first component and the second component is generated. The electrostatic field strength image 432 is a visual representation of the target object 104 and the plurality of measures of electrostatic field strength.

A third electrostatic event 428 and a fourth electrostatic event 430 are detected by the processor 140, according to some embodiments. In some embodiments, the third electrostatic event 428 is detected based upon one or more pixels associated with one or more points or regions corresponding to the valve manifold box 414 (shown in FIG. 12). In some embodiments, the third electrostatic event 428 is detected based upon a determination that the one or more pixels are one or more colors of the defined set of colors associated with electrostatic events. In some embodiments, the third electrostatic event 428 is detected based upon a determination that the one or more pixels are indicative of measures of electrostatic field strength that exceed the threshold measure of electrostatic field strength. In some embodiments, the third electrostatic event 428 is detected based upon a determination that a change in pixel color over time, of the one or more pixels, is indicative of a change in electrostatic field strength that exceeds the threshold change in electrostatic field strength. In some embodiments, the third electrostatic event 428 is detected using the trained machine learning model. In some embodiments, at least one of the third electrostatic event 428 or the fourth electrostatic event 430 is a result of fluid, such as high resistance fluid, flowing through the valve manifold box 414.

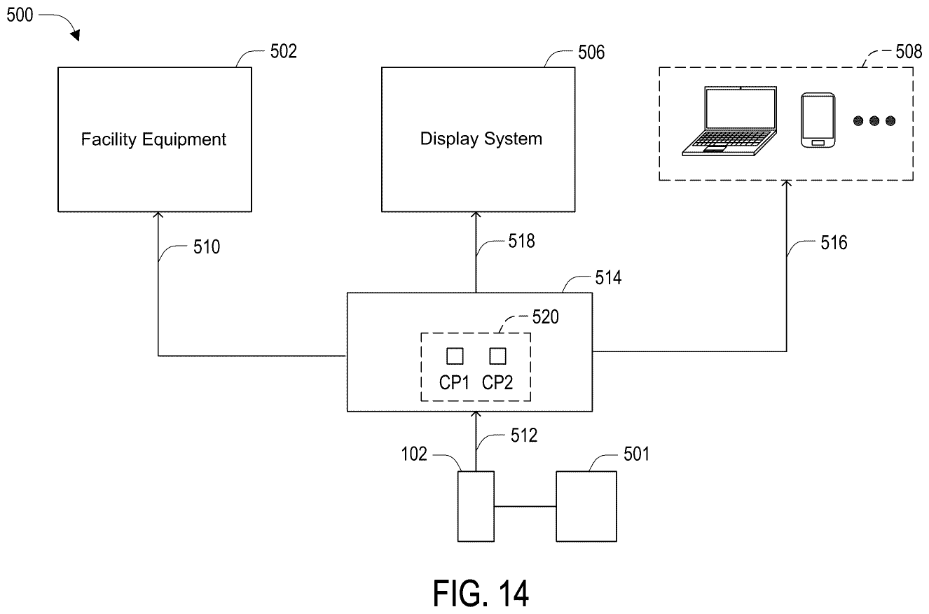

FIG. 14 illustrates a schematic view of a system 500, in accordance with some embodiments. The system 500 includes at least one of the apparatus 102 described above, facility equipment 502 of a facility, a controller 514, an electrostatic information display system 506, or one or more client devices 508. In one embodiment, the apparatus 102 may be coupled to a mobile or portable device or vehicle to be moved around a facility. For example, the apparatus 102 may be integrated with a mobile device 501, such as an overhead hoist transport (OHT), an automatic material handling system (AMHS), an unmanned aerial vehicle (UAV), a robot arm, or the like, in an industrial facility where semiconductor devices are fabricated, such that the apparatus 102 can follow a predetermined route map and/or a track of the mobile device 501 to be transported along a floor, a ceiling, or a wall of the industrial facility, so as to measure the electrostatic field strength for various equipment distributed at various locations of the facility. In other embodiment, the system 500 may include a plurality of apparatuses 102 described above for measuring the electrostatic field strength for various equipment distributed at various locations of the facility at the same time. In some embodiments, the apparatuses 102 is an electrostatic field monitoring apparatus, which is used to perform electrostatic field strength measurements of a plurality of target object, such as semiconductor fabrication components, throughout the facility. The target objects include at least one of (i) one or more components including PVD equipment, such as plasma enhanced PVD equipment, (ii) one or more components including CVD equipment, (iii) one or more components including plating equipment, (iv) one or more components including etching equipment, (v) one or more components including lithography equipment, (vi) one or more components including CMP equipment, (vii) one or more components including semiconductor wafer storage equipment, such as one or more FOUPs, (viii) one or more components that that utilize plasma, (ix) one or more components including one or more tubes, such as one or more pipes or one or more other type of tubes that are configured to conduct at least one of liquid or gas, (x) one or more manifolds, (xi) one or more components including fluid storage equipment, (xii) one or more processing chambers, (xiii) one or more pumps, (xiv) one or more robotic arms, (xv) one or more stocker tools, (xvi) one or more management tools, (xvii) one or more handling tools, (xviii) inspection equipment, (xix) one or more components of an automated material handling system, (xx) one or more components of an automated transport system, (xxi) a lorry tank, (xxii) one or more masks, (xxiii) one or more mask boxes, or (xxiv) one or more other components.

In some embodiments, the system 500 may include one or more electrostatic field monitoring apparatuses 102 configured to transmit a set of electrostatic field signals 512 to the controller 514. In some embodiments, a first electrostatic field signal of the set of electrostatic field signals 512 is provided by a first electrostatic field monitoring apparatus of the electrostatic field monitoring apparatuses 102, a second electrostatic field signal of the set of electrostatic field signals 512 is provided by a second electrostatic field monitoring apparatus of the electrostatic field monitoring apparatuses 102, etc.

In some embodiments, the first electrostatic field monitoring apparatus is positioned at least one of proximate a first component of the plurality of components or facing the first component, and is configured to at least one of (i) determine measures of electrostatic field strength associated with the first component, (ii) generate electrostatic field strength maps associated with the first component, or (iii) detect electrostatic events associated with the first component. In some embodiments, the first electrostatic field signal is indicative of at least one of the measures of electrostatic field strength associated with the first component or the electrostatic field strength maps associated with the first component. In some embodiments, in response to the first electrostatic field monitoring apparatus detecting an electrostatic event, the first electrostatic field monitoring apparatus includes an indication of the electrostatic event in the first electrostatic field signal, thereby informing the controller 514 of the electrostatic event.

In some embodiments, the second electrostatic field monitoring apparatus is positioned at least one of proximate a second component of the plurality of components or facing the second component, and is configured to at least one of (i) determine measures of electrostatic field strength associated with the second component, (ii) generate electrostatic field strength maps associated with the second component, or (iii) detect electrostatic events associated with the second component. In some embodiments, the second electrostatic field signal is indicative of at least one of the measures of electrostatic field strength associated with the second component or the electrostatic field strength maps associated with the second component. In some embodiments, in response to the second electrostatic field monitoring apparatus detecting an electrostatic event, the second electrostatic field monitoring apparatus includes an indication of the electrostatic event in the second electrostatic field signal, thereby informing the controller 514 of the electrostatic event.

In other embodiment, the first electrostatic field signal of the set of electrostatic field signals 512 and the second electrostatic field signal of the set of electrostatic field signals 512 can be provided by one electrostatic field monitoring apparatus 102 integrated with a mobile device, such as an overhead hoist transport (OHT), a robot arm, or the like, in an industrial facility where semiconductor devices are fabricated, such that the electrostatic field monitoring apparatus 102 is configured to be moved between various locations for monitoring the electrostatic field of different components in the industrial facility.

Accordingly, the electrostatic field monitoring apparatus 102 is moved to be positioned at least one of proximate a first component of the plurality of components or facing the first component, and is configured to at least one of (i) determine measures of electrostatic field strength associated with the first component, (ii) generate electrostatic field strength maps associated with the first component, or (iii) detect electrostatic events associated with the first component. In some embodiments, the first electrostatic field signal is indicative of at least one of the measures of electrostatic field strength associated with the first component or the electrostatic field strength maps associated with the first component. In some embodiments, in response to the first electrostatic field monitoring apparatus detecting an electrostatic event, the first electrostatic field monitoring apparatus includes an indication of the electrostatic event in the first electrostatic field signal, thereby informing the controller 514 of the electrostatic event.

Then, the electrostatic field monitoring apparatus 102 is positioned at least one of proximate a second component of the plurality of components or facing the second component, and is configured to at least one of (i) determine measures of electrostatic field strength associated with the second component, (ii) generate electrostatic field strength maps associated with the second component, or (iii) detect electrostatic events associated with the second component. In some embodiments, the second electrostatic field signal is indicative of at least one of the measures of electrostatic field strength associated with the second component or the electrostatic field strength maps associated with the second component. In some embodiments, in response to the second electrostatic field monitoring apparatus detecting an electrostatic event, the second electrostatic field monitoring apparatus includes an indication of the electrostatic event in the second electrostatic field signal, thereby informing the controller 514 of the electrostatic event.

Thus, in accordance with some embodiments, the one or more electrostatic field monitoring apparatuses 102 determine electrostatic field strength information associated with the plurality of components throughout the facility, and provide the electrostatic field strength information to the controller 514 via the set of electrostatic field signals 512. In some embodiments, the electrostatic field strength information of the set of electrostatic field signals 512 is indicative of one or more electrostatic events detected by one or more electrostatic field monitoring apparatuses 102. In some embodiments, instead of the one or more electrostatic events being detected by the one or more electrostatic field monitoring apparatuses 102, the set of electrostatic field signals 512 provided by the one or more electrostatic field monitoring apparatuses 102 are indicative of at least one of measures of electrostatic field strength or electrostatic field strength maps associated with the plurality of components, wherein the at least one of the measures of electrostatic field strength or the electrostatic field strength maps are analyzed by the controller 514 to detect the one or more electrostatic events.

In some embodiments, the controller 514 includes a set of status indicators 520 associated with components of the plurality of components of the facility. In some embodiments, an indicator of the set of status indicators 520 includes a light, such as indicator light, that indicates whether or not an electrostatic event at a component in the facility is detected, wherein the light being in a first state indicates that an electrostatic event at the component is detected and/or the light being in a second state indicates that an electrostatic event at the component is not detected. In some embodiments, the first state corresponds to a first color emitted by the light, such as red or other color, and the second state corresponds to a second color emitted by the light, such as green or other color. The set of status indicators includes at least one of a first indicator “CP1” associated with the first component, a second indicator “CP2” associated with the second component. Certainly, more than two indicators associated with more than two components may be applied.

In some embodiments, the controller 514 determines electrostatic status information associated with the plurality of components of the facility. The electrostatic status information indicates at least one of whether or not an electrostatic event at a component of the plurality of components is detected, one or more components of the plurality of components associated with one or more detected electrostatic events, or other information.

In some embodiments, the controller 514 provides one or more first signals 510 to the facility equipment 502. In some embodiments, the one or more first signals 510 are used to control at least some of the facility equipment 502, such as one, some, and/or all of the plurality of components of the facility. In some embodiments, the one or more first signals 510 are generated using a signal generator of the controller 514. The one or more first signals 510 are indicative of at least one of the electrostatic status information or other information. In some embodiments, the controller 514 transmits the one or more first signals 510 to the facility equipment 502 wirelessly, such as using a wireless communication device of the controller 514. In some embodiments, the controller 514 transmits the one or more first signals 510 to the facility equipment 502 over a physical connection between the controller 514 and the facility equipment 502.

In some embodiments, the controller 514 transmits a second signal 518 to the electrostatic information display system 506. The second signal 518 is generated using the signal generator of the controller 514. In some embodiments, the second signal 518 is indicative of one or more electrostatic field strength maps, such as one or more electrostatic field strength images, generated using electrostatic field monitoring devices of the set of electrostatic field monitoring devices 504. In some embodiments, the second signal 518 is indicative of one or more detected electrostatic events. In some embodiments, the controller 514 transmits the second signal 518 to the electrostatic information display system 506 wirelessly, such as using the wireless communication device of the controller 514. In some embodiments, the controller 514 transmits the second signal 518 to the electrostatic information display system 506 over a physical connection between the controller 514 and the electrostatic information display system 506.

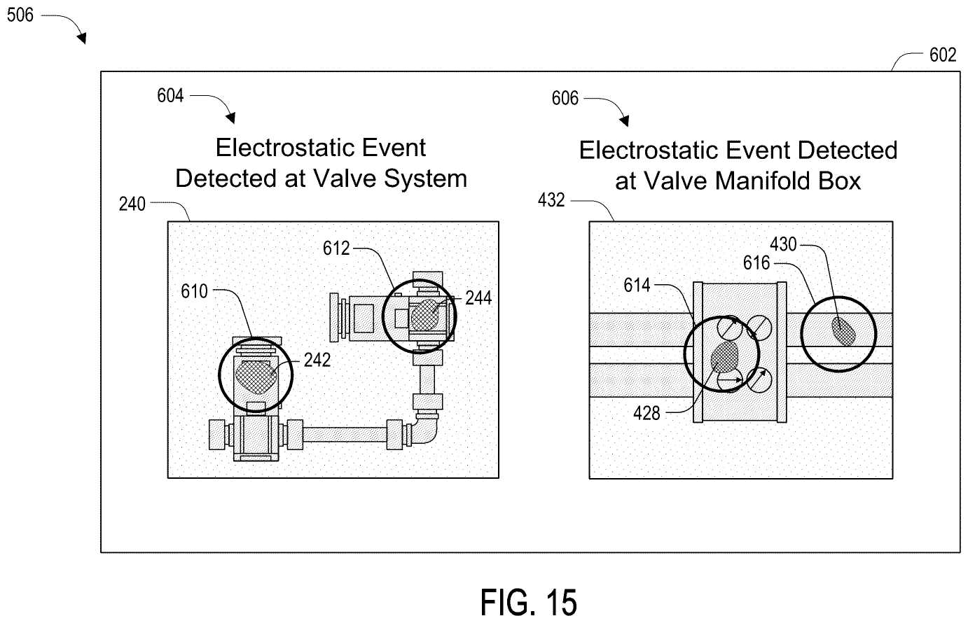

FIG. 15 illustrates an electrostatic information display system 506 displaying electrostatic event information, in accordance with some embodiments. In some embodiments, a display 602 of the electrostatic information display system 560 is controlled to display at least one of one or more electrostatic field strength maps, one or more electrostatic field strength measures, alerts of one or more detected electrostatic events, etc.

In some embodiments, the display 602 displays a first alert 604 associated with the first electrostatic event 242 and the second electrostatic event 244 associated with at least one of the first valve 204 and the second valve 206. In some embodiments, the first alert 604 may include information that identifies where the first electrostatic event 242 and the second electrostatic event 244 are located. In some embodiments, the first alert 604 includes a representation of the electrostatic field strength image 240. In some embodiments, the representation of the electrostatic field strength image 240 includes indications 610 and 612 that overlay the electrostatic field strength image 240 and identify regions corresponding to the first electrostatic event 242 and the second electrostatic event 244.

In some embodiments, the display 602 may also display a second alert 606 associated with the third electrostatic event 428 and the fourth electrostatic event 430 associated with the valve manifold box 414 (shown in FIG. 12). In some embodiments, the second alert 606 includes information that identifies where the third electrostatic event 428 and the fourth electrostatic event 430 are located. In some embodiments, the second alert 606 includes a representation of the electrostatic field strength image 432. In some embodiments, the representation of the electrostatic field strength image 432 includes indications 614 and 616 that overlay the electrostatic field strength image 432 and identify regions corresponding to the third electrostatic event 428 and the fourth electrostatic event 430.

Referring to FIG. 3 and FIG. 15, In some embodiments, the material of the first valve 204 and the second valve 206 is different from the material of the valve manifold box 414 (shown in FIG. 12). Accordingly, the first wavelength of first light signal 108a and the second wavelength of the second light signal 108b, emitted by the first photodiodes 1161 and the second photodiodes 1162 respectively, can be predetermined corresponding to the material of the of the first valve 204 and the second valve 206 and the material of the valve manifold box 414 for measuring the electrostatic field strength of the valves 204, 206 and the valve manifold box 414. Then, the electrostatic field strength map including the electrostatic field strength images 240 and 432 for the valves 204, 206 and the valve manifold box 414 are generated respectively.

Thus, in accordance with some embodiments, in response to detection of an electrostatic event in the facility, the electrostatic information display system 506 automatically alerts a viewer of the display 602 of the electrostatic event and where the electrostatic event is located, thereby enabling the viewer to address the electrostatic event before the electrostatic event causes damage to one or more components in the facility by at least one of ESD, arcing, micro-arcing, or other event.

In some embodiments, the controller 514 (shown in FIG. 14) transmits a third signal 516 to one or more client devices 508. The one or more client devices 508 include at least one of a phone, a smartphone, a mobile phone, a landline, a laptop, a desktop computer, hardware, or other type of client device. The third signal 516 is generated using the signal generator of the controller 514. In some embodiments, the third signal 516 is indicative of one or more electrostatic field strength maps, such as one or more electrostatic field strength images, generated using electrostatic field monitoring devices of the set of electrostatic field monitoring devices 504. In some embodiments, the third signal 516 is indicative of one or more detected electrostatic events. In some embodiments, the controller 514 transmits the third signal 516 to a client device of the one or more client devices 508 wirelessly, such as using the wireless communication device of the controller 514. In some embodiments, the controller 514 transmits the third signal 516 to a client device of the one or more client devices 508 over a physical connection between the controller 514 and the client device. In some embodiments, a client device of the one or more client devices 508 triggers an alarm based upon the third signal 516. In some embodiments, the client device triggers the alarm based upon the third signal 516 indicating that an electrostatic event is detected in the facility. In some embodiments, in response to triggering the alarm, an alarm message is displayed via the client device. The alarm message includes at least one of an indication that an electrostatic event is detected in the facility, one or more indications of one or more components of the facility at which an electrostatic event is detected, or other indication. In some embodiments, an alarm sound is output via a speaker connected to the client device in response to triggering the alarm. In some embodiments, the third signal 516 includes a message, such as at least one of an email, a text message, etc., transmitted in response to detecting an electrostatic event in the facility. In some embodiments, in response to detecting an electrostatic event in the facility, a telephonic call is made to a client device, such as a landline or a mobile phone, of the one or more client devices 508, such as using a dialer of the controller 514.

In some embodiments, equipment of the facility equipment 502 ceases operation based upon a signal of the one or more first signals 512, received by the equipment, at least one of indicating that an electrostatic event is detected at a component associated with the equipment or indicating an instruction to cease the operation of the equipment. In some embodiments, the signal indicates the instruction to cease the operation of the equipment based upon a determination, by the controller 514, that an electrostatic event is detected at the component associated with the equipment. In some embodiments, the component is at least one of connected to or a part of the equipment that ceases operation. In some embodiments, ceasing operation of the equipment includes at least one of powering off one or more components of the equipment, disconnecting a power supply from one or more components of the equipment, the equipment entering a mode in which the equipment does not perform one or more operations, or other action.

In some embodiments, the equipment transfers from a first mode to a second mode based upon the signal at least one of indicating that an electrostatic event is detected or indicating an instruction to transfer from the first mode to the second mode. In some embodiments, the first mode is a mode in which the equipment performs one or more first operations and the second mode is a mode in which the equipment performs one or more second operations different than the one or more first operations. In some embodiments, the first mode is a mode in which at least one of a component of the equipment is unlocked or access to the component is not blocked and the second mode is a mode in which at least one of the component is locked or access to the component is blocked. In some embodiments, the first mode is a mode in which at least one of one or more functions of the equipment are enabled or initiation of a new process using the one or more functions is not blocked and the second mode is a mode in which at least one of the one or more functions of the equipment are disabled or initiation of a new process using the one or more functions is blocked.

Thus, in accordance with some embodiments, in response to detection of an electrostatic event in the facility, the controller 514 controls the equipment of the facility equipment 502 to automatically perform one or more actions, including at least one of cease operation, change modes, block one or more functions, or other action, that prevent the detected electrostatic event from causing damage to one or more components in the facility by at least one of ESD, arcing, micro-arcing, or other event.

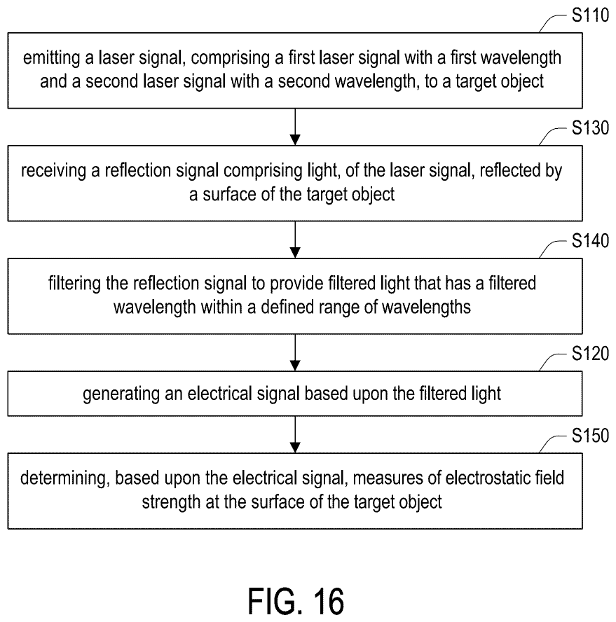

FIG. 16 is a flow diagram illustrating a method, in accordance with some embodiments. A method of measuring electrostatic field strength of a target object is illustrated in FIG. 16 in accordance with some embodiments. Referring to FIG. 3 and FIG. 16, at step S110, a light signal, including a first light signal 108a with a first wavelength and a second light signal 108b with a second wavelength, is emitted to a target object 104. In some embodiments, the first light signal 108a and the second light signal 108b are generated by the ring light source 116 includes a plurality of first photodiodes 1161 for emitting the first light signal 108a and a plurality of second photodiodes 1162 for emitting the second light signal 108b. In one embodiment, the ring light source 116 is a laser source in a ring shape, and configured to emit a laser signal 108 to the target object 104. The first wavelength of the first light signal 108a is different from the second wavelength of the second light signal 108b for detecting the electrostatic field strengths on different materials at the surface 106 of the target object 104.

At step S120, a reflection signal is received, wherein the reflection signal including light, of the light signal, is reflected by a surface 106 of the target object 104. In one embodiment, reflection signal includes a first reflection signal 118a and a second reflection signal 118b. That is, the first reflection signal 118a of the first light signal 108a is reflected by the surface 106 of the target object 104, and the second reflection signal 118b of the second light signal 108b is reflected by the surface 106 of the target object 104. In some embodiments, the reflection detector 124 is disposed within and surrounded by the ring light source 116 and configured to receive the first reflection signal 118a of the first light signal 108a and the second reflection signal 118b of the second light signal 108b, which are reflected by the surface 106 of the target object 104.

At step S130, the reflection signal is filtered to provide filtered light that has a filtered wavelength within a defined range of wavelengths. In one embodiment, the first reflection signal 118a is filtered by the optical filter 134a to provide a first filtered light that has a filtered wavelength within a defined range of wavelengths 128a, and the second reflection signal 118b is filtered by the optical filter 134b to provide a second filtered light that has a filtered wavelength within a defined range of wavelengths 128b.

At S140, an electrical signal is generated based upon the filtered light. In one embodiment, the electrical signal include a first electrical signal and a second electrical signal. The first electrical signal is generated by the light sensor 136 based upon the first filtered light, while the second electrical signal is generated by the light sensor 136 based upon the second filtered light.

At S150, measures of electrostatic field strength at the surface 106 of the target object 104 is determined based upon the electrical signal. In one embodiment, measures of electrostatic field strength at the surface 106 of the target object 104 is determined by the processor 140 based upon the first electrical signal and the second electrical signal.

In some embodiments, the processor 140 generates an electrostatic field strength map based upon the plurality of measures of electrostatic field strength. In some embodiments, the computer 140 detects an electrostatic event based upon the plurality of measures of electrostatic field strength. In some embodiments, the electrostatic event is detected based upon the electrostatic field strength map. In some embodiments, an alert, indicative of the electrostatic event, is displayed via a display 142, or a signal indicative of the electrostatic event is provided.

In some embodiments, a plurality of electrostatic field strength maps generated in association with the target object 104 over a period of time are retrieved, and a machine learning model is trained using the plurality of electrostatic field strength maps to generate a trained machine learning model. The detection of the electrostatic event is performed using the trained machine learning model.

In some embodiments, the target object 104 includes a semiconductor fabrication equipment. In such embedment, the semiconductor fabrication process is started in response to a determination that a first measure of electrostatic field strength of the one or more measures of electrostatic field strength meets a first threshold, such as a first threshold measure of electrostatic field strength. In some embodiments, the semiconductor fabrication component initiates performing the semiconductor fabrication process when the semiconductor fabrication process is started. In some embodiments, the first measure of electrostatic field strength meets the first threshold when the first measure of electrostatic field strength exceeds the first threshold. In some embodiments, the first measure of electrostatic field strength meets the first threshold when the first measure of electrostatic field strength is less than the first threshold. In some embodiments, the semiconductor fabrication process is started in response to a determination that one, some, and/or all of the one or more measures of electrostatic field strength meet the first threshold. In some embodiments, the semiconductor fabrication process is started in response to a determination that at least a threshold proportion of the one or more measures of electrostatic field strength meet the first threshold.

In some embodiments, the semiconductor fabrication process is completed in response to a determination that a second measure of electrostatic field strength of the one or more measures of electrostatic field strength meets a second threshold, such as a second threshold measure of electrostatic field strength. The second measure of electrostatic field strength is the same as or different than the first measure of electrostatic field strength. The second threshold is the same as or different than the first threshold. In some embodiments, the semiconductor fabrication component initiates one or more completion acts of the semiconductor fabrication process to complete the semiconductor fabrication process. In some embodiments, the one or more completion acts light at least one of rinsing the semiconductor wafer, drying the semiconductor wafer, or other completion act. In some embodiments, the semiconductor fabrication component stops performing acts of the semiconductor fabrication process to complete the semiconductor fabrication process. In some embodiments, the second measure of electrostatic field strength meets the second threshold when the second measure of electrostatic field strength exceeds the second threshold. In some embodiments, the second measure of electrostatic field strength meets the second threshold when the second measure of electrostatic field strength is less than the second threshold. In some embodiments, the semiconductor fabrication process is completed in response to a determination that one, some, and/or all of the one or more measures of electrostatic field strength meet the second threshold. In some embodiments, the semiconductor fabrication process is completed in response to a determination that at least a threshold proportion of the one or more measures of electrostatic field strength meet the second threshold.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, an electrostatic field strength measuring apparatus includes an electrostatic field detection device and a processor. The electrostatic field detection device includes a ring light source configured to emit a light signal to a target object, and a reflection detector disposed within and surrounded by the ring light source and configured to receive a reflection signal, of the light signal, reflected by a surface of the target object and generate an electrical signal based upon the reflection signal. The processor is configured to determine, based upon the electrical signal, measures of electrostatic field strength at the surface of the target object. In one embodiment, the ring light source includes a plurality of first photodiodes configured to emit a first light signal with a first wavelength to the target object, and a plurality of second photodiodes configured to emit a second light signal with a second wavelength to the target object, wherein the first wavelength is different from the second wavelength. In one embodiment, the reflection signal includes a first reflection signal, of the first light signal, reflected by the surface of the target object and a second reflection signal, of the second light signal, reflected by the surface of the target object. In one embodiment, the electrical signal includes a first electrical signal generated based upon the first reflection signal, and a second electrical signal generated based upon the second reflection signal. In one embodiment, the reflection detector includes a first optical filter, a second optical filter, and a light sensor. The first optical filter is configured to block light, of the first reflection signal, that has a wavelength outside a first defined range of wavelengths, and provide a first filtered light, from the first reflection signal, that has a wavelength within the first defined range of wavelengths. The second optical filter is configured to block light, of the second reflection signal, that has a wavelength outside a second defined range of wavelengths, and provide a second filtered light, from the second reflection signal, that has a wavelength within the second defined range of wavelengths. The light sensor is configured to generate the first electrical signal and the second electrical signal based upon the first filtered light and the second filtered light respectively. In one embodiment, the reflection detector further includes a first optical sensor coupled to the first optical filter and the light sensor and configured to receive the first filtered light passing through the first optical filter, and a second optical sensor coupled to the second optical filter and the light sensor and configured to receive the second filtered light passing through the second optical filter. In one embodiment, the first light signal or the second light signal has an initial wavelength, and the first defined range of wavelengths or the second defined range of wavelengths includes a reflected wavelength substantially equal to half of the initial wavelength. In one embodiment, the reflection detector includes one or more lenses configured to conduct the first reflection signal to the first optical filter and conduct the second reflection signal to the second optical filter. In one embodiment, the processor is configured to: determine a pixel color based upon a measure of electrostatic field strength of the measures of electrostatic field strength; and generate one or more pixels of an electrostatic field strength map according to the pixel color. In one embodiment, the electrostatic field strength measuring apparatus includes a display configured to display the one or more pixels of the electrostatic field strength map.

In accordance with some embodiments of the disclosure, a detecting apparatus includes a ring light source, and a reflection detector. The ring light source includes a plurality of first photodiodes configured to emit a first light signal with a first wavelength to a target object and a plurality of second photodiodes configured to emit a second light signal with a second wavelength to the target object. Thea reflection detector is disposed within and surrounded by the ring light source and configured to receive a first reflection signal of the first light signal and a second reflection signal of the second light signal reflected by a surface of the target object and generate a first electrical signal and a second electrical signal based upon the first reflection signal and the second reflection signal respectively. In one embodiment, a power of the first light signal is substantially equal to a power of the second light signal. In one embodiment, the reflection detector includes an optical filter and a light sensor. The optical filter is configured to filter the first reflection signal and the second reflection signal and provide a first filtered light, from the first reflection signal, with a first wavelength within a first defined range of wavelengths, and a second filtered light, from the second reflection signal, with a second wavelength within a second defined range of wavelengths. The light sensor is configured to generate the first electrical signal and the second electrical signal based upon the first filtered light and the second filtered light. In one embodiment, the reflection detector includes one or more lenses configured to conduct the reflection signal to the optical filter. In one embodiment, the detecting apparatus further includes a processor configured to determine, based upon the first electrical signal and the second electrical signal, measures of a characteristic of the target object. In one embodiment, the characteristic includes an electrostatic field strength at the surface of the target object, a dimension of the surface of the target object, or a distance from the reflection detector to the surface of the target object.

In accordance with some embodiments of the disclosure, a method of measuring electrostatic field strength of a target object includes: emitting a light signal, including a first light signal with a first wavelength and a second light signal with a second wavelength, to a target object; receiving a reflection signal including light, of the light signal, reflected by a surface of the target object; filtering the reflection signal to provide filtered light that has a filtered wavelength within a defined range of wavelengths; generating an electrical signal based upon the filtered light; and determining, based upon the electrical signal, measures of electrostatic field strength at the surface of the target object. In one embodiment, the method includes: generating an electrostatic field strength map based upon the measures of electrostatic field strength; detecting an electrostatic event based upon the electrostatic field strength map; and at least one of: displaying an alert, indicative of the electrostatic event, via a display; or providing a signal indicative of the electrostatic event. In one embodiment, the method includes: retrieving a plurality of electrostatic field strength maps generated in association with the target object over a period of time; and training a machine learning model using the plurality of electrostatic field strength maps to generate a trained machine learning model, wherein detecting the electrostatic event is performed using the trained machine learning model. In one embodiment, the target object includes a semiconductor fabrication equipment, and the method further includes: starting a semiconductor fabrication process by the semiconductor fabrication equipment in response to a determination that a first measure of electrostatic field strength of meets a first threshold; or completing the semiconductor fabrication process in response to a determination that a second measure of electrostatic field strength meets a second threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electrostatic field strength measuring apparatus, comprising:
a ring-shaped light source comprising a plurality of photodiodes and configured to emit a light signal to a target object;
a reflection detector surrounded by the plurality of photodiodes, wherein the reflection detector is configured to receive a reflection signal, of the light signal, reflected by a surface of the target object and generate an electrical signal based upon the reflection signal; and
a processor configured to determine, based upon the electrical signal, measures of electrostatic field strength at the surface of the target object.

2. The electrostatic field strength measuring apparatus as claimed in claim 1, wherein the plurality of photodiodes comprises:
a plurality of first photodiodes configured to emit a first light signal with a first wavelength to the target object; and
a plurality of second photodiodes configured to emit a second light signal with a second wavelength to the target object, wherein the first wavelength is different from the second wavelength.

3. The electrostatic field strength measuring apparatus as claimed in claim 2, wherein the reflection signal comprises a first reflection signal, of the first light signal, reflected by the surface of the target object and a second reflection signal, of the second light signal, reflected by the surface of the target object.

4. The electrostatic field strength measuring apparatus as claimed in claim 3, wherein the electrical signal comprises a first electrical signal generated based upon the first reflection signal, and a second electrical signal generated based upon the second reflection signal.

5. The electrostatic field strength measuring apparatus as claimed in claim 4, wherein the reflection detector comprises:
a first optical filter configured to block light, of the first reflection signal, that has a wavelength outside a first defined range of wavelengths, and provide a first filtered light, from the first reflection signal, that has a wavelength within the first defined range of wavelengths;
a second optical filter configured to block light, of the second reflection signal, that has a wavelength outside a second defined range of wavelengths, and provide a second filtered light, from the second reflection signal, that has a wavelength within the second defined range of wavelengths; and
a light sensor configured to generate the first electrical signal and the second electrical signal based upon the first filtered light and the second filtered light respectively.

6. The electrostatic field strength measuring apparatus as claimed in claim 5, wherein the reflection detector further comprises:
a first optical sensor coupled to the first optical filter and the light sensor and configured to receive the first filtered light passing through the first optical filter; and
a second optical sensor coupled to the second optical filter and the light sensor and configured to receive the second filtered light passing through the second optical filter.

7. The electrostatic field strength measuring apparatus as claimed in claim 5, wherein:
the first light signal or the second light signal has an initial wavelength; and
the first defined range of wavelengths or the second defined range of wavelengths comprises a reflected wavelength substantially equal to half of the initial wavelength.

8. The electrostatic field strength measuring apparatus as claimed in claim 5, wherein:
the reflection detector comprises one or more lenses configured to conduct the first reflection signal to the first optical filter and conduct the second reflection signal to the second optical filter.

9. The electrostatic field strength measuring apparatus as claimed in claim 1, wherein the processor is configured to:
determine a pixel color based upon a measure of electrostatic field strength of the measures of electrostatic field strength; and
generate one or more pixels of an electrostatic field strength map according to the pixel color.

10. The electrostatic field strength measuring apparatus as claimed in claim 8, comprising:
a display configured to display the one or more pixels of the electrostatic field strength map.

11. A detecting apparatus, comprising:
a ring-shaped light source comprising a plurality of photodiodes and configured to emit a light signal to a target object; and
a reflection detector disposed within the ring-shaped light source and surrounded by the plurality of photodiodes, wherein the reflection detector is configured to receive a reflection signal, of the light signal, reflected by a surface of the target object.

12. The detecting apparatus as claimed in claim 11, wherein reflection detector is configured to generate an electrical signal based upon the reflection signal.

13. The detecting apparatus as claimed in claim 11, wherein the plurality of photodiodes comprises:
a plurality of first photodiodes configured to emit a first light signal with a first wavelength to the target object; and
a plurality of second photodiodes configured to emit a second light signal with a second wavelength to the target object, wherein the first wavelength is different from the second wavelength.

14. The detecting apparatus as claimed in claim 13, wherein the reflection signal comprises a first reflection signal, of the first light signal, reflected by the surface of the target object and a second reflection signal, of the second light signal, reflected by the surface of the target object and the reflection detector is configured to generate a first electrical signal and a second electrical signal based upon the first reflection signal and the second reflection signal respectively.

15. The detecting apparatus as claimed in claim 13, wherein a power of the first light signal is substantially equal to a power of the second light signal.

16. The detecting apparatus as claimed in claim 14, wherein the reflection detector comprises:
an optical filter configured to filter the first reflection signal and the second reflection signal and provide a first filtered light, from the first reflection signal, with a first wavelength within a first defined range of wavelengths, and a second filtered light, from the second reflection signal, with a second wavelength within a second defined range of wavelengths; and
a light sensor configured to generate the first electrical signal and the second electrical signal based upon the first filtered light and the second filtered light.

17. The detecting apparatus as claimed in claim 16, wherein:
the reflection detector comprises one or more lenses configured to conduct the reflection signal to the optical filter.

18. A method of measuring electrostatic field strength of a target object, comprising:
emitting a light signal to a target object by a plurality of photodiodes arranged in a ring shape;
receiving a reflection signal, of the light signal, reflected by a surface of the target object by a reflection detector surrounded by the plurality of photodiodes;
filtering the reflection signal to provide filtered light that has a filtered wavelength within a defined range of wavelengths;
generating an electrical signal based upon the filtered light; and
determining, based upon the electrical signal, measures of electrostatic field strength at the surface of the target object.

19. The method as claimed in claim 18, comprising:
generating an electrostatic field strength map based upon the measures of electrostatic field strength;
detecting an electrostatic event based upon the electrostatic field strength map; and
at least one of:
displaying an alert, indicative of the electrostatic event, via a display; or
providing a signal indicative of the electrostatic event.

20. The method as claimed in claim 18, wherein the target object comprises a semiconductor fabrication equipment, and the method further comprises:
starting a semiconductor fabrication process by the semiconductor fabrication equipment in response to a determination that a first measure of electrostatic field strength of meets a first threshold; or
completing the semiconductor fabrication process in response to a determination that a second measure of electrostatic field strength meets a second threshold.
